(19) United States
(12) Patent Application Publication
(10) Pub. No.: US 2024/0234567 A1
(43) Pub. Date: Jul. 11, 2024

(54) BURIED SHIELD STRUCTURES FOR POWER SEMICONDUCTOR DEVICES INCLUDING SEGMENTED SUPPORT SHIELD STRUCTURES FOR REDUCED ON-RESISTANCE AND RELATED FABRICATION METHODS

(71) Applicant: Wolfspeed, Inc., Durham, NC (US)

(72) Inventors: Madankumar Sampath, Durham, NC (US); Naeem Islam, Morrisville, NC (US); Woongsun Kim, Cary, NC (US); Sei-Hyung Ryu, Cary, NC (US)

(21) Appl. No.: 18/472,343

(22) Filed: Sep. 22, 2023

Related U.S. Application Data
(63) Continuation-in-part of application No. 18/150,432, filed on Jan. 5, 2023.

(51) Int. Cl. H01L 29/78; H01L 29/40

(52) U.S. Cl. CPC H01L 29/7813; H01L 29/407

(57) ABSTRACT

A semiconductor device includes a semiconductor layer structure comprising a drift region of a first conductivity type and a well region of a second conductivity type above the drift region, a gate on the semiconductor layer structure adjacent the well region, and a contact shielding structure of the second conductivity type that vertically extends from the well region into the drift region, and discontinuously extends in one or more lateral directions. Related devices and fabrication methods are also discussed.

### CROSS-REFERENCE TO RELATED APPLICATIONS

The present application is a continuation-in-part of and claims priority to U.S. patent application Ser. No. 18/150,432, filed on Jan. 5, 2023, the contents of which are incorporated by reference herein in its entirety.

### FIELD

The present invention relates to semiconductor devices and, more particularly, to power semiconductor devices.

### BACKGROUND

Power semiconductor devices refer to devices that include one or more “power” semiconductor die that are designed to carry large currents (e.g., tens or hundreds of Amps) and/or that are capable of blocking high voltages (e.g., hundreds, thousand or tens of thousands of volts). A wide variety of power semiconductor devices are known in the art including, for example, power Metal Insulator Semiconductor Field Effect Transistors (“MISFETs”, including Metal Oxide Semiconductor FETs (“MOSFETs”)), bipolar junction transistors (“BJTs”), Insulated Gate Bipolar Transistors (“IGBT”), Junction Barrier Schottky diodes, Gate Turn-Off Transistors (“GTO”), MOS-controlled thyristors, and various other devices. These power semiconductor devices are generally fabricated from wide bandgap semiconductor materials, for example, silicon carbide (“SiC”) or Group III nitride (e.g., gallium nitride (“GaN”))-based semiconductor materials. Herein, a wide bandgap semiconductor material refers to a semiconductor material having a bandgap greater than about 1.40 eV, for example, greater than about 2 eV.

A conventional power semiconductor device typically has a semiconductor substrate having a first conductivity type (e.g., an n-type substrate) on which an epitaxial layer structure having the first conductivity type (e.g., n-type) is formed. A portion of this epitaxial layer structure (which may comprise one or more separate layers) functions as a drift layer or drift region of the power semiconductor device. The device typically includes an “active region,” which includes one or more “unit cell” structures that have a junction, for example, a p-n junction. The active region may be formed on and/or in the drift region. The active region acts as a main junction for blocking voltage in the reverse bias direction and providing current flow in the forward bias direction. The power semiconductor device may also have an edge termination in a termination region that is adjacent the active region. One or more power semiconductor devices may be formed on the substrate, and each power semiconductor device will typically have its own edge termination. After the substrate is fully processed, the resultant structure may be diced to separate the individual edge-terminated power semiconductor devices.

Power semiconductor devices may have a unit cell configuration in which a large number of individual unit cell structures of the active region are electrically connected (e.g., in parallel) to function as a single power semiconductor device. In high power applications, such a power semiconductor device may include thousands or tens of thousands of unit cells implemented in a single chip or “die.” A die or chip may include a small block of semiconducting material or other substrate in which electronic circuit elements are fabricated. For example, a plurality of individual power semiconductor devices may be formed on a relatively large semiconductor substrate (e.g., by growing epitaxial layers there on doping selected regions with dopants, forming insulation and metal layers thereon, etc.) and the completed structure may then be cut (e.g., by a sawing or dicing operation) into a plurality of individual die, each of which is a power semiconductor device.

Power semiconductor devices can have a lateral structure or a vertical structure. In a device having a lateral structure, the terminals of the device (e.g., the drain, gate and source terminals for a power MOSFET device) are on the same major surface (e.g., top or bottom) of a semiconductor layer structure. In contrast, in a device having a vertical structure, at least one terminal is provided on each major surface of the semiconductor layer structure (e.g., in a vertical MOSFET device, the source may be on the top surface of the semiconductor layer structure and the drain may be on the bottom surface of the semiconductor layer structure). The semiconductor layer structure may or may not include an underlying substrate. Herein, the term “semiconductor layer structure” refers to a structure that includes one or more semiconductor layers, including semiconductor substrates and/or semiconductor epitaxial layers.

Vertical power semiconductor devices, such as MOSFET or IGBT devices, can have a standard gate electrode design in which the gate electrode of the transistor is formed on top of the semiconductor layer structure (referred to herein as planar gate devices) or, alternatively, may have the gate electrode buried in a trench within the semiconductor layer structure (referred to as gate trench devices). With the standard gate electrode design, the channel region of each unit cell transistor is horizontally disposed underneath the gate electrode. In contrast, in the gate trench design, the channel is vertically disposed. Gate trench devices may provide enhanced performance, but typically require more complex manufacturing processes.

Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential. As the applied voltage approaches or passes the voltage level that the device is designed to block, non-trivial levels of current (referred to as leakage current) may begin to flow through the power semiconductor device. The blocking capability of the device may be a function of, among other things, the doping density/concentration and thickness of the drift region. Leakage currents may also arise for other reasons, such as failure of the edge termination and/or the primary junction of the device. If the voltage applied to the device is increased beyond the breakdown voltage to a critical level, the increasing electric field may result in an uncontrollable and undesirable runaway generation of charge carriers within the semiconductor device, leading to a condition known as avalanche breakdown.

### SUMMARY

According to some embodiments, a semiconductor device includes a semiconductor layer structure comprising a drift region of a first conductivity type and a well region of a second conductivity type above the drift region; a gate on the semiconductor layer structure adjacent the well region; and a contact shielding structure of the second conductivity type that vertically extends into the drift region and discontinuously extends in one or more lateral directions.

In some embodiments, the contact shielding structure includes a plurality of discrete segments that longitudinally extend in the one or more lateral directions, respectively. For example, the contact shielding structure may include support shielding structures that longitudinally extend in a first lateral direction and are spaced apart from the gate. Additionally or alternatively, the contact shielding structure may include bridge shielding structures that extend in a second lateral direction, which crosses the first lateral direction, to contact a bottom shielding structure of the second conductivity type in the drift region under the gate.

In some embodiments, at least one of the support shielding structures or the bridge shielding structures comprises the discrete segments.

In some embodiments, the semiconductor layer structure further includes a gate trench having opposing sidewalls and a bottom surface therebetween extending into the drift region, where the gate is in the gate trench. The bottom shielding structure may extend under the bottom surface of the gate trench.

In some embodiments, the bridge shielding structures extend along both of the opposing sidewalls of the gate trench.

In some embodiments, the bridge shielding structures comprise the discrete segments, one of the opposing sidewalls of the gate trench comprises one of the bridge shielding structures thereon, and another of the opposing sidewalls of the gate trench is free of the one of the bridge shielding structures.

In some embodiments, the bottom shielding structure continuously extends under the gate.

In some embodiments, the bottom shielding structure includes one or more discrete segments that extend under the gate.

In some embodiments, the semiconductor device further includes a buried shielding structure that extends in one or more lateral directions under the well region and is separated therefrom by a portion of the drift region.

In some embodiments, the bottom shielding structure and/or the gate has a linear, elliptical, or polygonal shape in plan view.

In some embodiments, at least a part of an electrical conduction path between the well region and a drain contact laterally extends under the bridge shielding structures.

In some embodiments, respective spacings between the discrete segments are aligned along a direction crossing the one or more lateral directions.

In some embodiments, respective spacings between the discrete segments are staggered along a direction crossing the one or more lateral directions.

In some embodiments, respective spacings between the discrete segments are less than respective widths of the discrete segments.

In some embodiments, the respective widths of the discrete segments are between about 0.1 and about 20 microns.

In some embodiments, the semiconductor layer structure further comprises a substrate, where the drift region is on the substrate, and a drain contact on the substrate opposite the drift region. Respective spacings between the discrete segments comprise portions of the semiconductor layer structure that are free of the contact shielding structure.

In some embodiments, the semiconductor layer structure further comprises a source region of the first conductivity type above the well region. A source contact is provided on a surface of the semiconductor layer structure opposite the drain contact. The source contact is electrically coupled to the source region and the contact shielding structure.

In some embodiments, the contact shielding structure comprises a material and/or dopant concentration that is different from that of the drift region.

According to some embodiments, a semiconductor device includes a semiconductor layer structure comprising a drift region of a first conductivity type and a well region of a second conductivity type above the drift region, a gate on the semiconductor layer structure adjacent the well region, a support shielding structure of the second conductivity type that vertically extends from the well region into the drift region and is spaced apart from the gate, and a bridge shielding structure of the second conductivity type that laterally extends from the support shielding structure towards the gate. At least one of the support shielding structure or the bridge shielding structure comprises a plurality of discrete segments.

In some embodiments, the discrete segments longitudinally extend in one or more lateral directions, respectively.

In some embodiments, the semiconductor device further includes a bottom shielding structure of the second conductivity type in the drift region under the gate, and the bridge shielding structure laterally extends from the support shielding structures to contact the bottom shielding structure.

In some embodiments, the semiconductor layer structure further includes a gate trench having opposing sidewalls and a bottom surface therebetween extending into the drift region, where the gate is in the gate trench, and the bottom shielding structure extends under the bottom surface of the gate trench.

In some embodiments, the bridge shielding structure extends along both of the opposing sidewalls of the gate trench.

In some embodiments, the bridge shielding structure comprises the discrete segments, one of the opposing sidewalls of the gate trench comprises the bridge shielding structure thereon, and another of the opposing sidewalls of the gate trench is free of the bridge shielding structure.

In some embodiments, the support shielding structure comprises a material and/or dopant concentration that is different from that of the bridge shielding structure.

In some embodiments, respective spacings between the discrete segments are less than respective widths of the discrete segments along a direction crossing the one or more lateral directions.

According to some embodiments, a semiconductor device includes a semiconductor layer structure comprising a drift region of a first conductivity type and a well region of a second conductivity type above the drift region, a gate on the semiconductor layer structure adjacent the well region, and a contact shielding structure of the second conductivity type that vertically extends from the well region into the drift region and comprises a plurality of segments with respective spacings therebetween. The respective spacings are smaller than respective widths of the segments.

In some embodiments, the respective widths of the segments are about 0.1 microns to about 20 microns.

In some embodiments, the semiconductor device has an avalanche capability that is increased by about 5% to about 30% and an on-resistance that is reduced by about 5% to about 30%, in comparison to a semiconductor device having a continuous shielding pattern.

In some embodiments, the segments longitudinally extend in one or more lateral directions, respectively, with the respective spacings therebetween.

In some embodiments, the respective spacings between the discrete segments are staggered along a direction crossing the one or more lateral directions.

In some embodiments, the respective spacings between the discrete segments are aligned along a direction crossing the one or more lateral directions.

In some embodiments, the semiconductor layer structure further comprises a substrate, where the drift region is on the substrate, and a drain contact on the substrate opposite the drift region. The respective spacings comprise portions of the semiconductor layer structure that are free of the contact shielding structure.

In some embodiments, the contact shielding structure comprises support shielding structures that extend in a first lateral direction and are spaced apart from the gate.

In some embodiments, the semiconductor device further includes a bottom shielding structure of the second conductivity type in the drift region under the gate. The contact shielding structure further comprises bridge shielding structures that extend in a second lateral direction, which crosses the first lateral direction, to contact the bottom shielding structure.

In some embodiments, at least one of the support shielding structures or the bridge shielding structures comprises the segments.

In some embodiments, at least a part of an electrical conduction path between the well region and a drain contact laterally extends under the bridge shielding structures.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1A is a schematic cross-sectional view illustrating an example unit cell of a gate trench power semiconductor device including bottom shielding regions positioned below the gate trenches.

FIG. 1B is a schematic cross-sectional view illustrating an example unit cell of a gate trench power semiconductor device including shielding regions that are positioned below and along one sidewall of the gate trenches.

FIG. 2A is a schematic cross-sectional view illustrating an example unit cell of a gate trench power semiconductor device including buried shielding structures according to some embodiments of the present disclosure.

FIG. 2B is a schematic cross-sectional view illustrating an example unit cell of a planar gate power semiconductor device including buried shielding structures according to some embodiments of the present disclosure.

FIGS. 3A and 3E are plan views illustrating patterns of buried shielding structures and gate electrodes (including gate trench or planar gate structures) according to some embodiments of the present disclosure. FIGS. 3B, 3C, and 3D are cross sectional views taken along lines B-B, C-C, and D-D of the gate trench structures of FIG. 3A or 3E.

FIGS. 4A and 4D are plan views illustrating patterns of buried shielding structures and gate electrodes (including gate trench or planar gate structures) according to some embodiments of the present disclosure. FIGS. 4B and 4C are cross sectional views taken along lines B′-B′ and C′-C′ of the gate trench structures of FIG. 4A or 4D.

FIG. 5A is a plan view illustrating patterns of buried shielding structures and gate electrodes (including gate trench or planar gate structures) according to some embodiments of the present disclosure. FIGS. 5B and 5C are cross sectional views taken along lines B″-B″ and C″-C″ of the gate trench structures of FIG. 5A.

FIG. 6 is a perspective view illustrating a gate trench power semiconductor device including buried shielding structures according to some embodiments of the present disclosure.

FIG. 7 is an equivalent circuit diagram illustrating transistor configurations that may be implemented in a power semiconductor device including buried shielding structures according to some embodiments of the present disclosure.

FIG. 8A is a plan view illustrating patterns of buried shielding structures and gate electrodes according to some embodiments of the present disclosure. FIGS. 8B, 8C, and 8D are cross sectional views taken along lines 8B-8B, 8C-8C, and 8D-8D of the gate trench structures of FIG. 8A.

FIG. 9A is a plan view illustrating patterns of buried shielding structures and gate electrodes according to some embodiments of the present disclosure. FIGS. 9B, 9C, and 9D are cross sectional views taken along lines 9B-9B, 9C-9C, and 9D-9D of the gate trench structures of FIG. 9A.

FIG. 10A is a plan view illustrating patterns of buried shielding structures and gate electrodes according to some embodiments of the present disclosure. FIGS. 10B and 10C are alternative examples of cross sectional views taken along line 10B/C-10B/C of the gate trench structure of FIG. 10A.

FIGS. 11A, 11B, 11C, 11D, and 11E are cross sectional views taken along lines B-B and C-C of the gate trench structure of FIG. 3A illustrating methods of fabricating power semiconductor devices including buried shielding structures according to some embodiments of the present disclosure.

FIGS. 12A, 12B, 12C, 12D, 12E, and 12F are cross sectional views taken along lines B-B and C-C of the gate trench structure of FIG. 3A illustrating methods of fabricating power semiconductor devices including buried shielding structures according to some embodiments of the present disclosure.

FIGS. 13A, 13B, 13C, 13D, and 13E are cross sectional views taken along lines B-B and C-C of the gate trench structure of FIG. 3A illustrating methods of fabricating power semiconductor devices including buried shielding structures according to some embodiments of the present disclosure.

FIGS. 14A, 14B, 14C, and 14D are cross sectional views taken along lines B-B and C-C of the planar gate structure of FIG. 3A illustrating methods of fabricating power semiconductor devices including buried shielding structures according to some embodiments of the present disclosure.

FIGS. 15A, 15B, 15C, and 15D are cross sectional views taken along lines B-B and C-C of the gate trench structure of FIG. 3A illustrating methods of fabricating power semiconductor devices including buried shielding structures according to some embodiments of the present disclosure.

FIG. 16A is a plan view illustrating patterns of contact shielding structures including segmented support shielding structures and gate electrodes according to some embodiments of the present disclosure. FIGS. 16B, 16C, and 16D are cross sectional views taken along lines 16B-16B, 16C-16C, and 16D-16D of the gate trench structures of FIG. 16A.

FIG. 17A is a plan view illustrating patterns of contact shielding structures including segmented support shielding structures and gate electrodes according to some embodiments of the present disclosure. FIGS. 17B, 17C, 17D, and 17E are cross sectional views taken along lines 17B-17B, 17C-17C, 17D-17D, and 17E-17E of the gate trench structures of FIG. 17A.

FIG. 18A is a plan view illustrating patterns of contact shielding structures including segmented support shielding structures and gate electrodes according to some embodiments of the present disclosure. FIGS. 18B, 18C, and 18D are cross sectional views taken along lines 18B-18B, 18C-18C, and 18D-18D of the gate trench structures of FIG. 18A.

FIG. 19A is a plan view illustrating patterns of contact shielding structures including segmented support shielding structures and gate electrodes according to some embodiments of the present disclosure. FIGS. 19B, 19C, and 19D are cross sectional views taken along lines 19B-19B, 19C-19C, and 19D-19D of the gate trench structures of FIG. 19A.

FIGS. 20A, 20B, and 20C are plan views illustrating patterns of contact shielding structures including segmented support shielding structures and square-shaped trenched gate electrodes according to some embodiments of the present disclosure.

FIGS. 21A, 21B, and 21C are plan views illustrating patterns of contact shielding structures including segmented support shielding structures and hexagonal-shaped trenched gate electrodes according to some embodiments of the present disclosure.

FIGS. 22A and 22B are plan views illustrating example segments of support shielding structures or bridge shielding structures according to some embodiments of the present disclosure.

### DETAILED DESCRIPTION OF EMBODIMENTS

Some embodiments of the present invention are directed to improvements in power semiconductor devices (e.g., MOSFETs, IGBTs, and other gate controlled power devices). In devices having gate electrodes and gate insulating layers formed within trenches in the semiconductor layer structure, high electric fields may degrade the gate insulating layer over time, and may eventually result in failure of the device. Deep shielding structures (also referred to herein as bottom shielding structures) may be provided underneath the gate trenches in order to reduce the electric field levels in the gate insulating layer, particularly at corners of the gate trenches where the electric field levels may be more concentrated. The bottom shielding structures may have the same conductivity type as the well regions, which is opposite the conductivity type of the drift region.

The bottom shielding structures may typically include highly doped semiconductor regions having the same conductivity type as the channel region. Methods for doping a semiconductor material with n-type and/or p-type dopants include (1) doping the semiconductor material during the growth thereof, (2) diffusing the dopants into the semiconductor material and (3) using ion implantation to selectively implant the dopants in the semiconductor material. When silicon carbide is doped during epitaxial growth, the dopants tend to unevenly accumulate, and hence the dopant concentration may vary by, for example, +/−15%, which can negatively affect device operation and/or reliability. Additionally, doping by diffusion may not be an option in silicon carbide, gallium nitride and various wide band-gap semiconductor devices since n-type and p-type dopants tend to not diffuse well (or at all) in those materials, even at high temperatures.

In light of the above, ion implantation is often used to dope wide band-gap semiconductor materials, such as silicon carbide. The depth at which the ions are implanted is directly related to the energy of the implant, i.e., ions implanted into a semiconductor layer at higher energies tend to go deeper into the layer. However, when dopant ions are implanted into a semiconductor layer, the ions damage the crystal lattice of the semiconductor layer. This lattice damage can typically only be partly repaired by thermal annealing processes. The amount of lattice damage may also be directly related to the implant energy, with higher energy implants tending to cause more lattice damage than lower energy implants. The uniformity of the dopant concentration also tends to decrease with increasing implant depth.

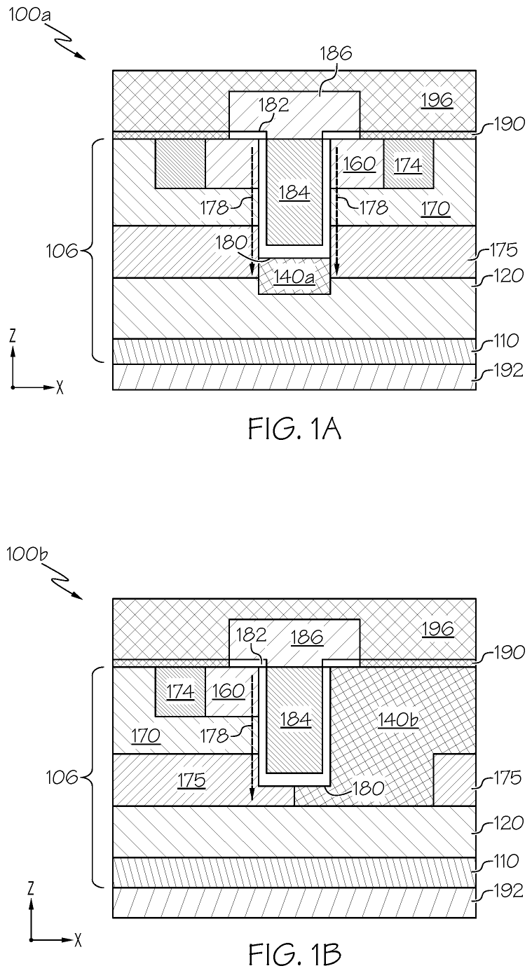

Various approaches may be used to form trenched vertical power semiconductor devices. FIGS. 1A and 1B schematically illustrate two examples of such different approaches.

FIGS. 1A and 1B are schematic cross-sectional views illustrating example transistor unit cells of trenched vertical power devices (illustrated as power MOSFET 100a and 100b, respectively) including bottom P-type shielding regions 140a, 140b. As shown in FIGS. 1A and 1B, the power MOSFET 100a, 100b each include a heavily-doped (e.g., N⁺) first conductivity type (e.g., n-type) substrate 110. A lightly-doped (e.g., N⁻) first conductivity type drift layer or region 120 is provided on the substrate 110, for example by epitaxial growth. The drift region 120 may be wide bandgap semiconductor material (such as silicon carbide (SiC)) in some embodiments. For example, the substrate 110 may be a 4H—SiC substrate, and the drift region 120 may be a 4H—SiC n-type epitaxial layer formed on the substrate 110. A portion of the drift region 120 may include a current spreading layer (“CSL”) 185 of the first conductivity type having a higher dopant concentration than the lower portions of the drift region 120. A moderately-doped second conductivity type (e.g., p-type) layer is formed on or in (for example, by epitaxial growth or implantation) the drift region 120 and acts as the well regions (e.g., “P-wells”) 170 for the device 100a, 100b. Heavily-doped second conductivity type (e.g., P⁺) regions 174 are formed in the well regions 170, for example, via ion implantation. The transistor channels or conduction paths 178 may be formed in the moderately-doped regions P-wells 170. The substrate 110, drift region 120 (including current spreading layer 185), and the moderately doped layer defining the P-wells 170, along with the various regions/patterns formed therein, are included in a semiconductor layer structure (denoted by 106 herein).

Still referring to FIGS. 1A and 1B, trenches 180 are formed in the semiconductor layer structure 106, e.g., with ‘striped’ gate trench layouts in which the trenches 180 continuously extend in parallel to one another in a first lateral direction. The trenches 180 are spaced apart in a second lateral direction crossing (e.g., perpendicular to) the first lateral direction, and extend into the drift region 120 toward the substrate 110 in a vertical direction. Lateral directions (e.g., the X-, Y-, or other directions in the X-Y plane) as described herein may be substantially perpendicular to vertical directions (e.g., the Z-direction) as described herein. The trenches 180 (in which the gates electrodes 184a are formed) may be formed to extend through the moderately-doped layer 170 to define the respective P-wells. Heavily-doped (e.g., P⁺) second conductivity type shielding structures 140a, 140b are formed in the drift region 120, for example, by ion implantation. The shielding structures 140a, 140b may be in electrical connection with the P-wells 170. A gate insulating layer 182a (e.g., a gate oxide) is conformally formed on the bottom surface and sidewalls of each trench 180. The corners of the gate trench 180 and the gate insulating layer 182 thereon may be rounded even if illustrated otherwise.

A gate electrode 184a (or “gate”) is formed on each gate insulating layer 182a to fill the respective gate trenches 180. Portions of the drift region 120 that are under the well regions 170 and/or adjacent a bottom of the gate electrode 184a may be referred to as “JFET” regions 175. Vertical transistor channel regions (with conduction 178 shown by dotted arrows) are defined in the well regions 170 adjacent the gate insulating layer 182a and controlled by the gate 184a. Heavily-doped source regions 160 of the first conductivity type (e.g. N⁺) are formed in upper portions of the P-wells 170, for example, via ion implantation. The heavily-doped regions 174 of the second conductivity type (e.g., a P+) contact the well regions 170. Source contacts 190 are formed on the source regions 160, on the heavily-doped regions 174, and (in FIG. 1B) on the deep shielding structures 140b. The source contacts 190 may be ohmic metal in some embodiments. A drain contact 192 is formed on the lower surface of the substrate 110. A gate contact (not shown) may be electrically connected to each gate electrode 184, for example, by a conductive gate bus (not shown). An intermetal dielectric layer 186 may be formed on the gates 184, and a metal (e.g., aluminum) layer 196 may be formed on the intermetal dielectric layer 186 to contact the source contacts 190. The source contacts 190 may extend on to the intermetal dielectric 186 layer in some embodiments, and may comprise, for example, diffusion barrier and/or adhesion layers.

As noted above, some devices may be susceptible to gate insulating layer degradation due to high electric fields, particularly in gate trench devices where electric fields may be concentrated at the trench corners. While bottom shielding structures may be provided underneath the gate trenches in order to reduce the electric field levels in the gate insulating layer, the bottom shielding structures should be electrically connected to the ohmic contact regions (on which the source metal may be formed) on the top surface of the device.

Embodiments of the present disclosure may provide buried shielding structures that laterally extend under and spaced apart from the well regions and/or gates, to provide electrical contact between contact shielding structures (which may vertically extend into the semiconductor layer structure) and the bottom shield structure. The buried shielding structures may be implemented without substantial loss of active area, as current can flow laterally in portions of the drift region between the well region and the buried shielding structure, and then vertically to the drain contact. The lateral extension of the buried shielding structure under multiple unit cells may allow for fewer or segmented source contacts in comparison to some conventional approaches, which may require a source contact in every unit cell. To increase or maximize conduction, the buried shielding structures may be implemented by relatively fine patterns, and/or a current spreading region with a higher concentration of dopants of the first conductivity type may be formed above and/or below the buried shielding structure. Buried shielding structures as described herein may also be used to implement a cascode configuration (e.g. including a JFET and MOSFET) between top and bottom surfaces of a semiconductor layer structure.

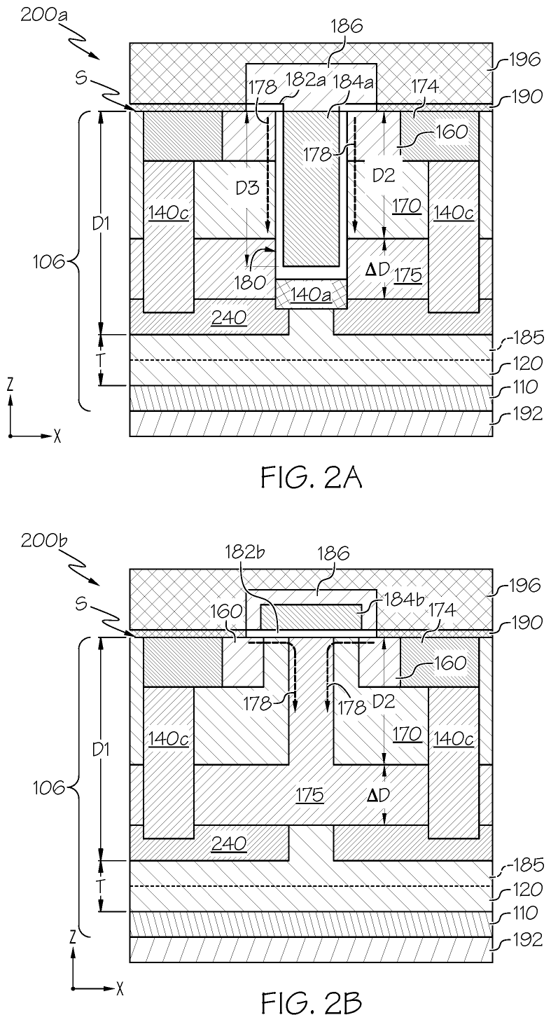

FIG. 2A is a schematic cross-sectional view illustrating an example unit cell of a gate trench power semiconductor device 200a including buried shielding structures 240 according to some embodiments of the present disclosure. FIG. 2B is a schematic cross-sectional view illustrating an example unit cell of a planar gate power semiconductor device 200b including buried shielding structures 240 according to some embodiments of the present disclosure.

As shown in the gate trench device 200a of FIG. 2A and the planar gate device 200b of FIG. 2B, the semiconductor layer structure 106 includes a drift region 120 of a first conductivity type (e.g., n-type) and a well region 170 of a second conductivity type (e.g., p-type) above the drift region 120. In the gate trench device 200a, the semiconductor layer structure 106 includes a gate trench 180 having sidewalls and a bottom surface therebetween extending into the drift region 120, with the gate 184a formed in the gate trench. In the planar gate device 200b, the gate 184b is formed on a surface S of the semiconductor layer structure 106. The gate 184a, 184b (collectively, 184) extends adjacent the well region 170 and is separated therefrom by a gate insulating layer 182a, 182b (collectively, 182), for example, a gate oxide layer. The source region, the well region 170, and the portion 175 of the drift region 120 under the well region 170 may provide p-n junctions of a first transistor TX1 in the semiconductor layer structure 106, with the well region 170 providing part of the transistor channel region that is controlled by the gate 184.

A buried shielding structure 240 of the second conductivity type extends under the well region 170 and is separated from the well region 170 by a portion 175 of the drift region 120 (e.g., the JFET region 175). The buried shielding structure 240 may have a different type or concentration of dopants of the second conductivity type than the well region 170, and may laterally extend in the drift region 120 (e.g., at a depth D1) between the well region 170 and the drain contact 192. The depth D1 of the buried shielding structure 240 in the drift region 120 may be greater than or equal to a depth D2 of the well region 170. The buried shielding structure 240 and the well region 170 are separated by a separation distance ΔD along the vertical (e.g., Z−) direction. The separation of the buried shielding structure 240 from the well region 170 (and likewise, from the bottom of the gate 184) may allow for improved current flow from the channel region to the drain at the device bottom. For example, the separation distance ΔD may be between about 0 to 4 micrometers (μm), or about 0.2 to 1.5 μm.

That is, the buried shielding structure 240 may be distinct from the well region 170 in material, dopant concentration, and/or depth relative to a surface S of the semiconductor layer structure 106. As described in greater detail below, the buried shielding structure 240 may be formed as a pattern including one or more segments 245 that extend in a first lateral direction (e.g., the X-direction), which may be different from a second lateral direction (e.g., the Y-direction) in which the gate 184 extends. The buried shielding structure 240 and the portions of the drift region 120 thereover and thereunder may provide p-n junctions of a second transistor TX2 in the semiconductor layer structure 106.

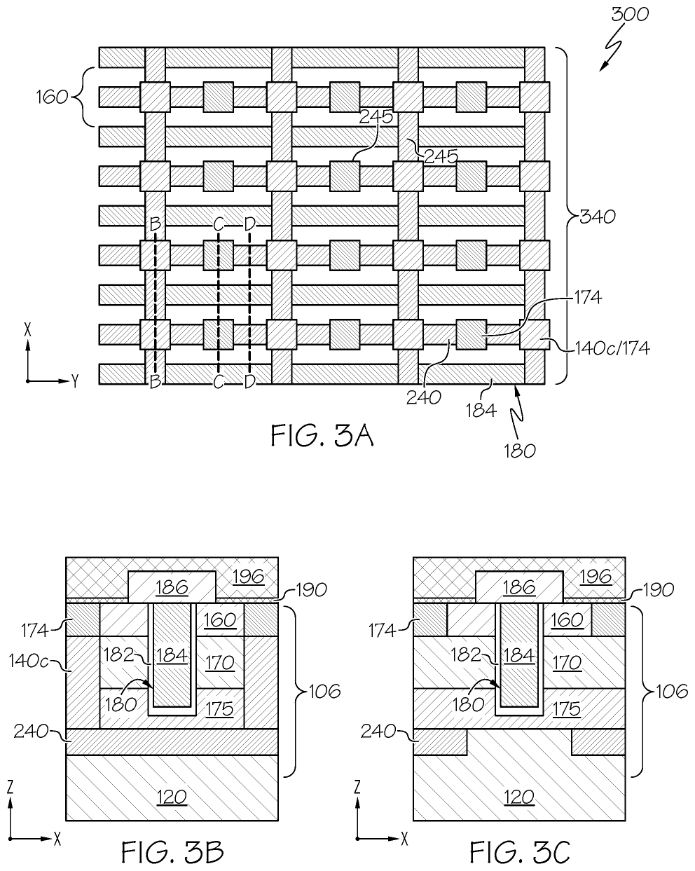

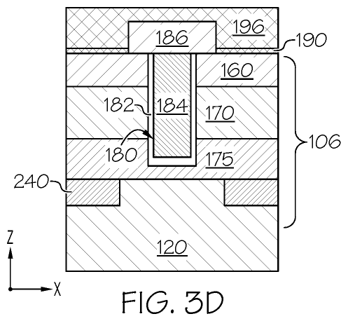

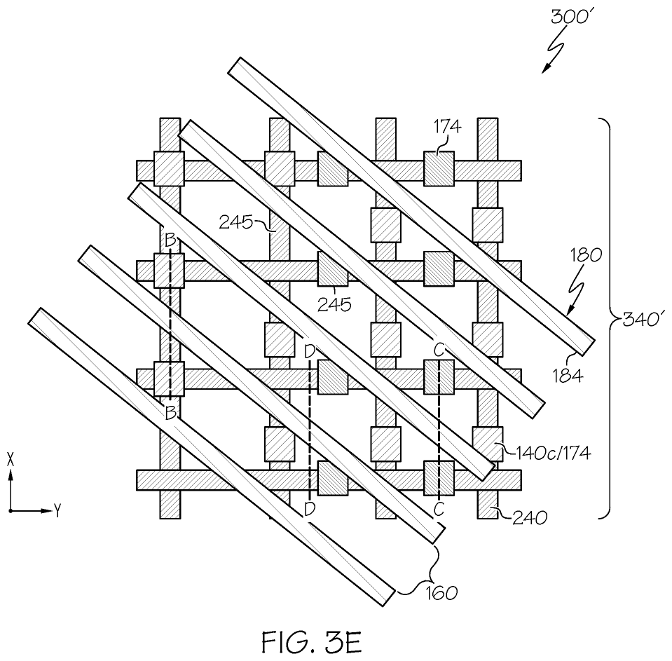

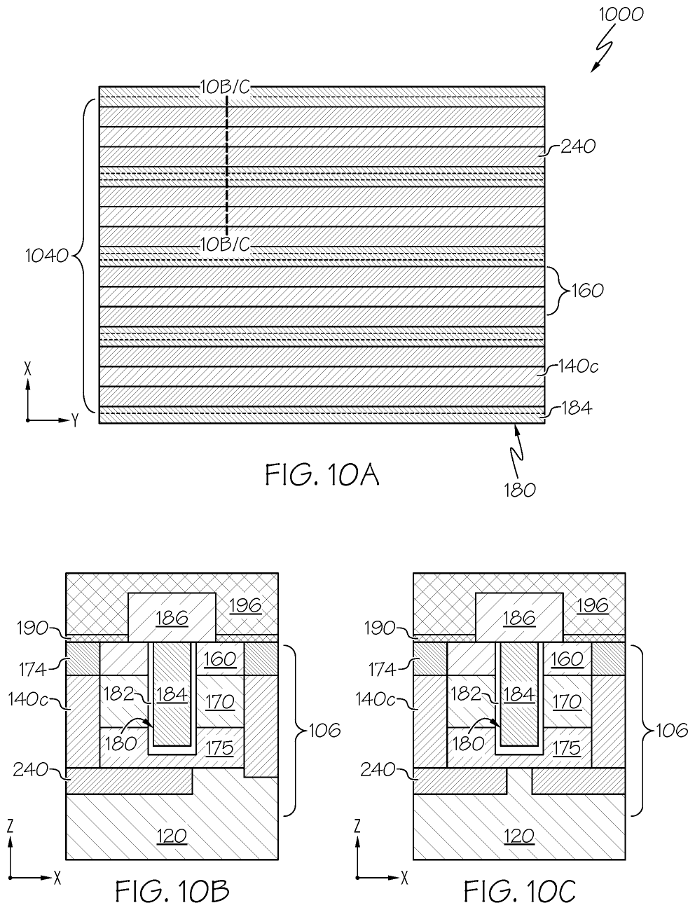

The cross sections of FIGS. 2A and 2B further illustrate at least one contact shielding structure 140c of the second conductivity type that vertically extends into the drift region 120 laterally spaced apart from the gate 184. In some embodiments, the contact shielding structure(s) 140c may be heavily doped (P⁺) silicon carbide regions formed by an ion implantation process. The buried shielding structure 240 laterally extends in the drift region 120 from under the well region 170 to at least one contact shielding structure 140c. The contact shielding structure 140c may electrically couple the source contact 190 to the buried shielding structure 240, e.g., for connection to electrical ground within a unit cell. The contact shielding structures 140c may have various shapes, including island-shapes (see, for example, FIG. 3A) or stripe-shapes (see, for example, FIG. 10A) in plan view. The contact shielding structure(s) 140c may also act as support shield structures that may reduce electric field levels in the gate oxide layers during device operation, and/or provide a low-resistance current path between the source and drain terminals of the MOSFET if avalanche breakdown occurs.

Portion(s) of the drift region 120 above and/or below the buried shielding structure 240 (more generally, between the well region 170 and the drain contact 192) may include an optional current spreading layer (CSL) or region 185 of the first conductivity type. The current spreading region 185 has a greater dopant concentration of the first conductivity type than the drift region 120. For example, for an n-type drift region 120, the current spreading region 185 may be an N+ region that is separated from the drain contact 192 by a lower portion of the drift region 120. In the gate trench device 200a, the gate trench 180 may extend to a depth D3 that is greater than the depth D2 of the well region 170, but less than the depth D1 of the buried shielding structure 240. For example, the gate trench 180 may have a depth D3 of between about 0.3 to about 10 microns relative to the surface S of the semiconductor layer structure 106. In some embodiments, a bottom shielding structure 140a of the second conductivity type is provided under the bottom surface of the gate trench. As noted above, the bottom shielding structure 140a may reduce the electric field levels in the gate insulating layer 182a, particularly at corners of the gate trench 180 where the electric field levels may be more concentrated. The buried shielding structure 240 laterally extends from the bottom shielding structure 140a to the at least one contact shielding structure 140c, thereby electrically coupling the bottom shielding structure 140a to the source region 160 and the source contact 190 (which may be an ohmic contact region of the surface S).

The buried shielding structure 240 and/or the contact shielding structure 140c may be formed of a material that is different from that of the drift region 120. For example, the drift region 120 may include a wide bandgap semiconductor material (such as silicon carbide and/or gallium nitride), while the buried shielding structure 240 and/or the contact shielding structure 140c may include polysilicon, nickel oxide, gallium nitride, or gallium oxide. The buried shielding structure 240 and/or the contact shielding structure 140c may be formed of a same or different material and/or with a similar or different dopant concentration than the bottom shielding structures 140a (when present). In some embodiments, the shielding structures 140c and/or 240 may be defined by one or more implantation processes, with substantially uniform concentration or stepwise or continuous grading. The contact shielding structures 140c may include a higher concentration of dopants of the second conductivity type (e.g., about 1×10¹⁷ to about 1×10²⁰ cm⁻³) as compared to the buried shielding structures 240 (e.g., e.g., about 1×10¹⁷ to about 5×10¹⁹ cm⁻³, or about 1×10¹⁸ to about 1×10¹⁹ cm⁻³). The dopant concentration of the shielding structures 140c and/or 240 may be higher than that of the well regions 170 (e.g., more than about 10 times higher; for example, about 100 times higher). The dopant concentrations of the shielding structures 140c and/or 240 may vary based on implementation of the fabrication process and/or device design.

The buried shielding structure 240 may be implemented in various shapes or patterns, in some embodiments with fewer than one contact shielding structure 140c (or source contact) per unit cell, in contrast to some conventional devices which may require contact shielding structures and/or source contacts in every unit cell. As such, in embodiments of the present disclosure, a greater portion of the semiconductor layer structure 106 may function as the device active area for electrical conduction, and more sparse or segmented source contacts 190 may be provided on the surface S of the semiconductor layer structure 106 to provide electrical connection to the source regions 160 and the contact shielding structures 140c (and thus, to the buried shielding structure 240). The number and/or distance between the source contacts 190 may be optimized based on electrical performance and/or reliability. For example, providing more source contacts 190 and/or contact shielding structures 140c may increase device on-resistance (e.g., due to reduction of available active area), while fewer source contacts 190 and/or contact shielding structures 140c may be problematic as device resistance would increase, resulting in greater losses in switching operation.

FIGS. 3A, 3E, 4A, 4D, and 5A, are plan views illustrating semiconductor devices 300, 300′, 400, 400′, and 500 including example patterns 340, 340′, 440, 440′, and 540 of buried shielding structures 240 and gate electrodes 184 (including gate trench or planar gate structures) according to some embodiments of the present disclosure As shown in FIGS. 3A, 3E, 4A, 4D, and 5A, the buried shielding structure 240 may define various patterns that laterally extend in the drift region 120 in plan view. The patterns may include segments 245 that extend in at least one lateral direction (e.g., in the X- and/or Y-directions shown in the figures), but it will be understood that embodiments of the present disclosure are not limited to the particular patterns 340, 340′, 440, 440′, and 540 shown.

In the example pattern 340 of FIG. 3A, the segments 245 of the buried shielding structure 240 extend linearly in one of (and are laterally spaced apart in the other of) a first lateral direction (e.g., the X-direction) or a second lateral direction (e.g., the Y-direction), while the gates 184 (or gate trenches 180) extend in the second lateral direction. In the example pattern 340′ of FIG. 3E, the segments 245 of the buried shielding structure 240 extend in the first lateral direction or in the second lateral direction, while the gates 184 (or gate trenches 180) extend in a third lateral direction (illustrated as diagonal to the first and second lateral directions). That is, FIGS. 3A and 3E illustrate example patterns 340, 340′ in which segments 245 of the buried shielding structure 240 may linearly extend in one or more lateral directions in plan view.

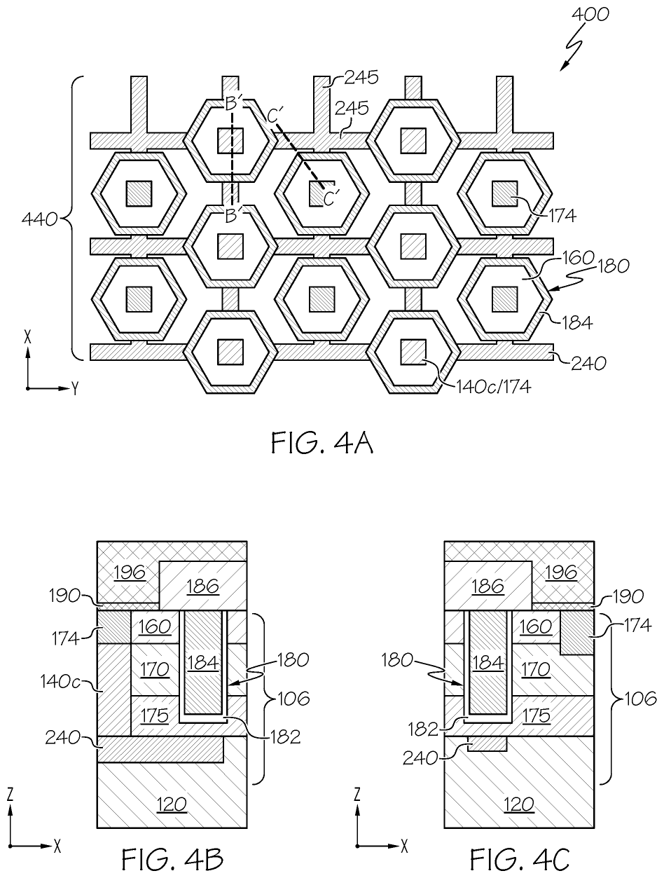

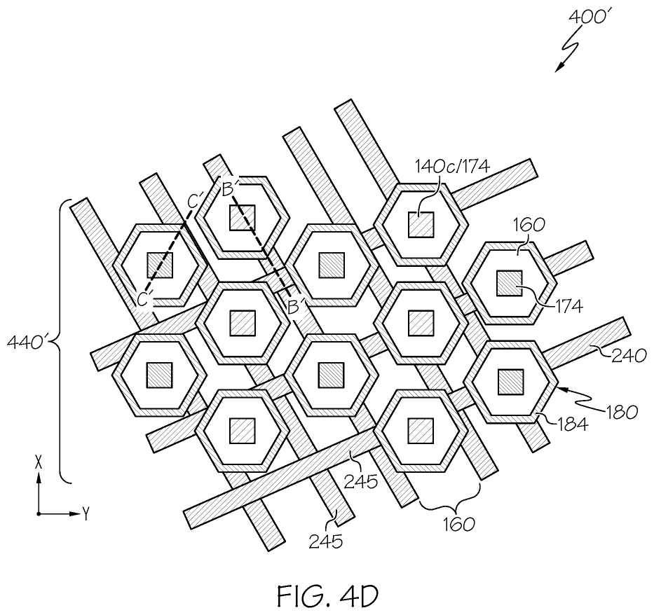

FIGS. 4A and 4D illustrate further examples of patterns 440, 440′ of the buried shielding structure 240 according to embodiments of the present disclosure. In the example pattern 440 of FIG. 4A, the segments 245 of the buried shielding structure 240 linearly extend in both a first lateral direction (e.g., the X-direction) and in a second lateral direction (e.g., the Y-direction), while the gates 184 (or gate trenches 180) extend in multiple lateral directions to define respective polygonal shapes in plan view. A respective well region 170 and/or contact shielding region may be provided within a perimeter of the respective polygonal shapes defined by the gates 184 or gate trenches 180. In the example pattern 440′ of FIG. 4D, the gates 184 (or gate trenches 180) again define polygonal shapes, but with the segments 245 of the buried shielding structure 240 linearly extending in first and second lateral directions that are diagonal to the X- and Y-directions in plan view.

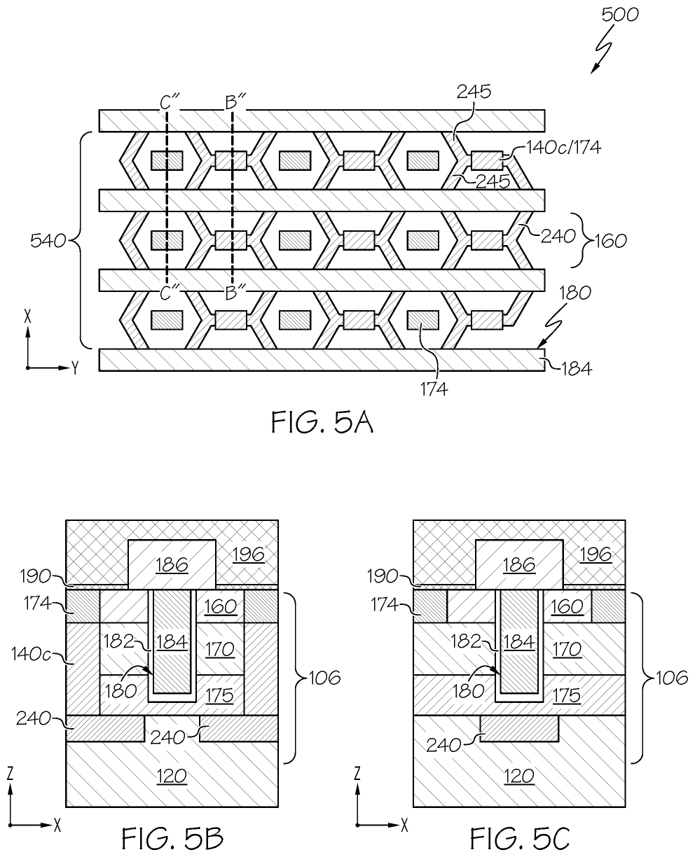

FIG. 5A illustrates a further example in which the gates 184 and buried shielding structure 240 are “reversed” relative to FIG. 4A, such that the gates 184 (or gate trenches 180) linearly extend in the second lateral direction (e.g., the Y-direction), while the segments 245 of the buried shielding structure 240 extend in multiple lateral directions to define polygonal shapes in plan view. The sides of the respective polygons are illustrated as being shared by adjacent segments 245, but the polygons defined by the segments 245 may be laterally separated from one another in some embodiments. Respective well regions 170 and/or contact shielding regions may be provided between the gates 184 or gate trenches 180. More generally, the buried shielding structure 240 and/or the gates 184/gate trenches 180 may define patterns including segments 245 that provide linear, elliptical, or polygonal shapes in plan view.

The patterns 340, 340′, 440, 440′, and 540 shown in FIGS. 3A, 3E, 4A, 4D, and 5A may include segments 245 having relatively fine lateral dimensions with comparatively wide spacings therebetween, so as to reduce or minimize obstruction of the active conduction area of the semiconductor structure. For example, a respective width of the one or more segments 245 along the direction in which the gates 184 (or gate trenches 180) extend) may be between about 0.1 and 20 microns.

FIGS. 3B, 3C, and 3D are cross sectional views taken along lines B-B, C-C, and D-D of the gate trench structures of FIG. 3A or 3E. FIGS. 4B and 4C are cross sectional views taken along lines B′-B′ and C′-C′ of the gate trench structures of FIG. 4A or 4D. FIGS. 5B and 5C are cross sectional views taken along lines B″-B″ and C″-C″ of the gate trench structures of FIG. 5A. In particular, FIGS. 3C, 4C, and 5C illustrate portions of the active area of the semiconductor layer structure 106 providing a primary conduction path from source to drain (also referred to herein as vertical conduction areas), while FIGS. 3B, 4B, and 5B illustrate portions of the active area of the semiconductor layer structure 106 providing both a conduction path and electrical connections to the buried shielding structure 240 (also referred to herein as lateral conduction areas).

As shown in FIGS. 3B, 4B, and 5B, in the lateral conduction areas, the buried shielding structure 240 may extend under (e.g., so as to at least partially overlap in the vertical or Z-direction) the well region 170 and/or under a bottom surface of the gate 184, and may be spaced apart or separated from the well region 170 and/or gate 184 by a portion 175 of the drift region 120. The buried shielding structure 240 laterally extends in the drift region 120 from under the well region 170 and/or gate 184 to at least one contact shielding structure 140c, which provides electrical connection to the source region 160 and the source contact 190 (or segment thereof) at the top surface S of the semiconductor structure. In the lateral conduction areas, the buried shielding structure 240 may laterally extend so as to completely or partially vertically overlap (in the Z-direction) with the gates 184, depending on the direction(s) of lateral extension of the segments 245 of the buried shielding structure 240 and the gates 184. In contrast, as shown in FIGS. 3C, 4C, and 5C, in the vertical conduction areas, the buried shielding structure 240 may vertically overlap with the well regions 170, but does not extend completely under the gate 184 (i.e., the buried shielding structure 240 may at most partially vertically overlap with the gates 184 in the Z-direction), thereby increasing the area of the semiconductor layer structure 106 that is available for conduction. As shown in FIGS. 4C and 5C, additional shallow contact structures 174 of the second conductivity type (e.g., P+ regions) may be provided in the vertical conduction areas for electrical contact to the well regions 170.

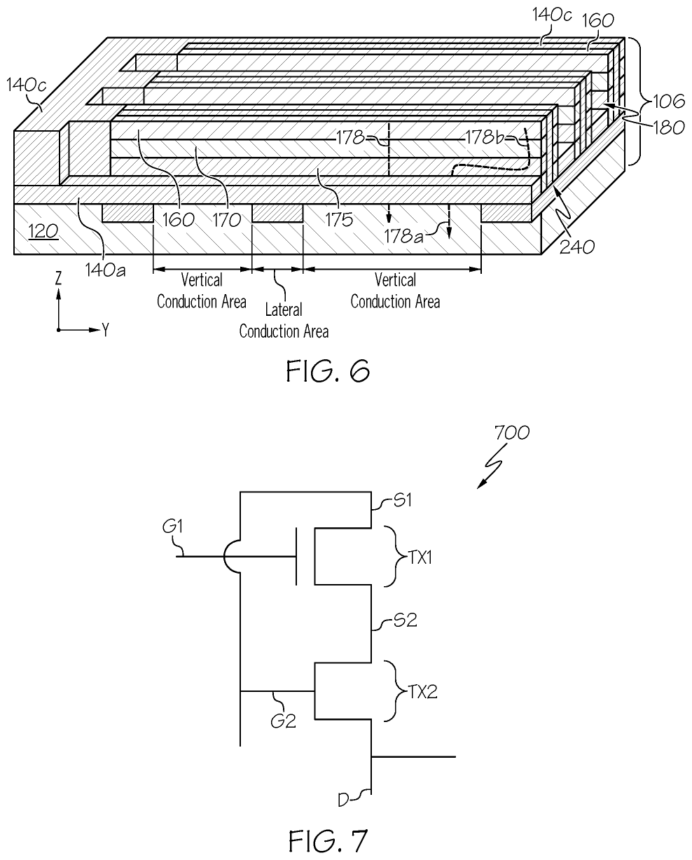

FIG. 6 is a perspective view illustrating lateral conduction areas and vertical conduction areas in a gate trench power semiconductor device 600 including a buried shielding structure 240 according to some embodiments of the present disclosure. As shown in FIG. 6, in some embodiments, the buried shielding structure 240 may include segments 245 that laterally extend in a first direction, and the contact shielding structures 140c may continuously extend in a second direction, laterally spaced apart from the gate trenches 180 in the first direction. A bottom shielding structure 140a of the second conductivity type may extend under the bottom surface of a respective gate trench. The buried shielding structure 240 laterally extends in the first direction from the bottom shielding structure 140a to one (or more) of the contact shielding structures 140c.

FIG. 6 further illustrates that the buried shielding structure 240 may be configured to provide a lateral conduction path in a portion 175 of the drift region 120 (e.g., the JFET region 175) between the bottom of the gate trench 180 and the buried shielding structure 240. In particular, the segments 245 of the buried shielding structure 240 are laterally spaced apart (in this example, along the Y-direction) such that at least a part of an electrical conduction path 178 between the well region 170 and the drain contact 192 laterally extends along the buried shielding structure 240 in the second lateral direction (e.g., the Y-direction). The electrical conduction path 178 thus includes at least a first conduction path 178a in a vertical (Z−) direction, a second conduction path 178b in a lateral (Y−) direction, and a third conduction path in the vertical (Z−) direction. That is, the buried shielding structure 240 defined by the patterns 340, 340′, 440, 440′, 540 may have one or more dimensions (in the lateral or vertical directions) that allow for lateral conduction (e.g., into or out of the page in the cross-sections of FIG. 3B, 4B, or 5B) around the relatively narrow segments 245 thereof to the drain contact 192.

In some embodiments, the segments 245 of the buried shielding structure 240 may have comparatively wide spacings therebetween, and may have relatively narrow widths in one or more lateral directions, such that the vertical conduction area of the semiconductor structure may be increased or maximized. That is, in any of the examples described herein, the lateral widths of the segments 245 of the buried shielding structure 240 may be reduced (and/or the lateral spacings between segments 245 of the buried shielding structure 240 may be increased) to increase the area of the semiconductor layer structure 106 that is available for electrical conduction. For example, a respective width of a segment of the buried shielding structure 240 along the second lateral direction (e.g., the Y-direction) may be between about 0.1 and 20 microns. Similarly, the number of contact shielding structures 140c may be reduced and/or the lateral spacings between contact shielding structures 140c(or segments 245 thereof) may be increased to provide desired or optimized performance.

FIG. 7 is an equivalent circuit diagram illustrating transistor configurations 700 that may be implemented using buried shielding structures 240 according to some embodiments of the present disclosure. Referring to the equivalent circuit diagram of FIG. 7 and the cross sectional views of FIGS. 2A and 2B, a semiconductor layer structure 106 includes a first surface S with the gate 184 adjacent thereto (whether on the surface S or in a gate trench 180 in the surface S), and an opposing second surface with the drain contact 192 thereon. The semiconductor layer structure 106 includes a first transistor TX1 and a second transistor TX2 that are electrically coupled (e.g., in a cascode amplifier configuration 700) between the first and second surfaces.

In detail, the source region, the well region 170, and a first portion 120a of the drift region 120 (between the well region 170 and the buried shielding structure 240) provide a first pair of p-n junctions 160/170/175 defining the first transistor TX1 in the semiconductor layer structure 106. The first portion 120a of the drift region 120, the buried shielding structure 240, and a second portion 120b of the drift region 120 (between the buried shielding structure 240 and the drain contact 192) provide a second pair of p-n junctions 175/240/120 defining the second transistor TX2 in the semiconductor layer structure 106. As such, the source region 160 provides a first source S1 of the first transistor TX1, and the first portion 120a of the drift region 120 (i.e., the JFET region 175) provides a second source S2 of the second transistor TX2. The gate 184 provides a first gate G1 of the first transistor TX1, and the buried shielding structure 240 provides a second gate G2 of the second transistor TX2. The second gate G2 of the second transistor TX2 (provided by the buried shielding structure 240) is electrically coupled (by the contact shielding region) to the first source S1 of the first transistor TX1 (provided by the source region), thereby providing the cascode amplifier configuration 700.

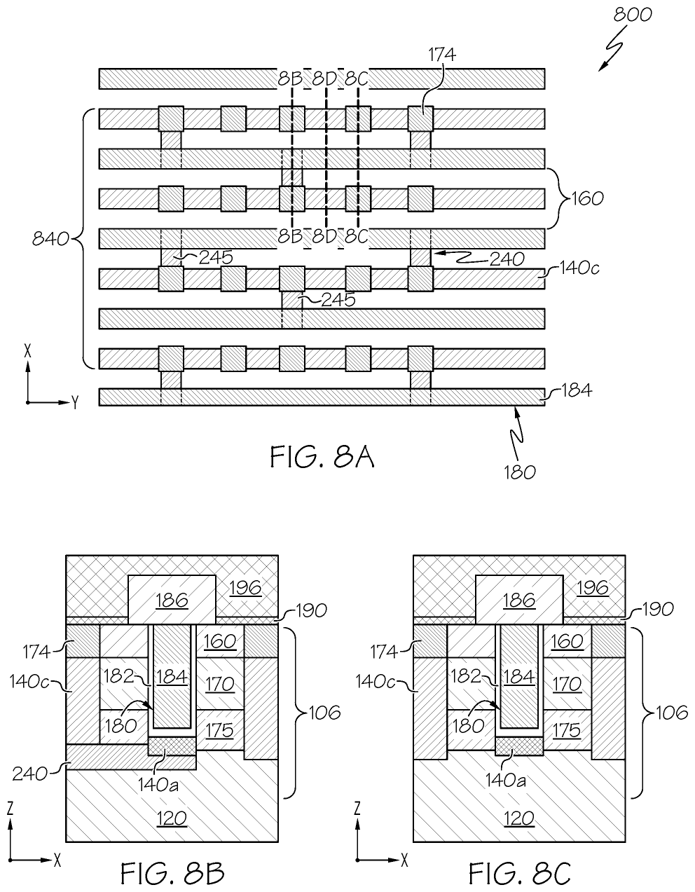

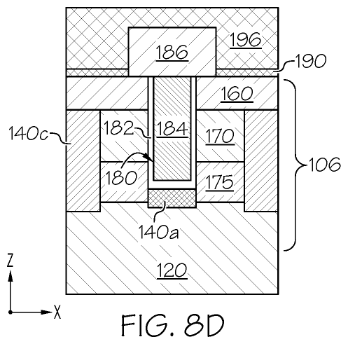

FIGS. 8A, 9A, and 10A, are plan views illustrating semiconductor devices 800, 900, 1000 including example patterns 840, 940, 1040 of buried shielding structures 240 and gate electrodes 184 extending in gate trenches 180 according to some embodiments of the present disclosure. As shown in FIGS. 8A, 9A, and 10A, the gates 184 and the contact shielding structures 140c continuously extend substantially parallel to one another in one lateral direction (e.g., the Y-direction), and the buried shielding structures 240 include patterns 840, 940, 1040 with segments 245 that discontinuously extend in a different lateral direction (e.g., the X-direction). However, it will be understood that embodiments of the present disclosure are not limited to the arrangements or patterns shown. For example, embodiments may include gates 184 and/or contact shielding structures 140c that are discontinuous or segmented in one or more lateral directions, segments 245 of the buried shielding structures 240 that are continuous in one or more lateral directions, or combinations thereof, with linear, elliptical, or polygonal shapes.

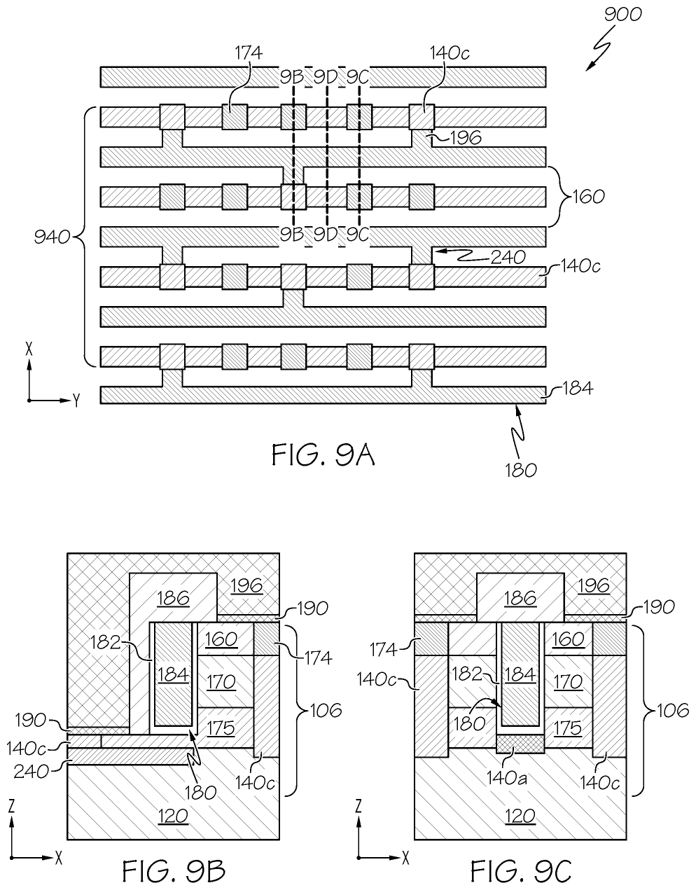

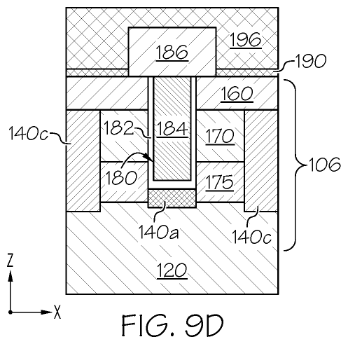

FIGS. 8B, 8C, and 8D are cross sectional views taken along lines 8B-8B, 8C-8C, and 8D-8D of the gate trench structures of FIG. 8A. FIGS. 9B, 9C, and 9D are cross sectional views taken along lines 9B-9B, 9C-9C, and 9D-9D of the gate trench structures of FIG. 9A. In particular, FIGS. 8C and 9C illustrate cross-sections of the vertical conduction areas, while FIGS. 8B and 9B illustrate cross-sections of the lateral conduction areas.

As shown in FIGS. 8B and 9B, in the lateral conduction areas, the buried shielding structure 240 laterally extends under the well region 170 and under a bottom surface of the gate 184, and is spaced apart or separated from the well region 170 by a portion 175 of the drift region 120. At least one contact shielding structure 140c of the second conductivity type vertically extends into the drift region 120 laterally spaced apart from the sidewalls of the gate trench 180 to contact the buried shielding structure 240, to provide electrical connection to a source contact 190 (or segment thereof) that is electrically coupled to the source region 160 at the top surface S of the semiconductor structure.

In the example of FIG. 8B, a bottom shielding structure 140a extends under the bottom surface of the gate trench, and the buried shielding structure 240 laterally extends from the bottom shielding structure 140a at the bottom of the gate trench 180 to at least one contact shielding structure 140c, thereby electrically coupling the buried shielding structure 240 and the bottom shielding structure 140a to the source contact. In some embodiments, the contact shielding structure 140c (shown as extending along the Y-direction) may also include segments 245 extending along the X-direction on one or both sidewalls of the gate trench 180 (i.e., forming a one-sided or two-sided “bridge”) in the lateral conduction areas. However, this arrangement may prevent conduction on one or both sides of the gate trench.

In the example of FIG. 9B, the buried shielding structure 240 is electrically coupled to the source contact 190 by a portion of the metal layer 196 on the source contact 190 (also referred to as the source contact metal). In particular, the source contact metal 196 extends laterally (in the X-direction) and vertically (in the Z-direction) along at least one of the sidewalls of the gate trench 180 to contact the buried shielding structure 240 (or a remaining portion of the contact shielding structure 140c in contact therewith). The source contact metal 196 may be separated from the sidewall(s) of the gate trench 180 by an interlayer dielectric material. This arrangement may likewise prevent conduction on one or both sides of the gate trench.

As shown in FIGS. 8C and 9C, in the vertical conduction areas, the buried shielding structure 240 does not extend under the gate 184, so as to increase the area of the semiconductor layer structure 106 that is available for conduction. In particular, the segments 245 of the buried shielding structure 240 are laterally spaced apart to define a relatively sparse pattern such that the buried shielding structure 240 is largely absent from the vertical conduction areas. The bottom shielding structure 140a may extend under the gate trench 180 in the vertical conduction areas, to reduce electric field levels in the gate insulating layer, particularly at corners of the gate trench.

FIGS. 10B and 10C are alternative examples of cross sectional views taken along line 10B/C-10B/C of the gate trench structure of FIG. 10A. In particular, FIGS. 10B and 10C illustrate alternative examples of vertical conduction areas in which the buried shielding structure 240 laterally extends under the well region 170 to at least partially vertically overlap (in the Z-direction) with the bottom of the gate trench. In some embodiments, the buried shielding structure 240 may extend under and spaced apart from the well region 170 at one side (in FIG. 10B) or both sides (in FIG. 10C) of the gate 184, in some embodiments over a majority of the drift region 120 between the contact shielding structures 140c and the gate 184.

More particularly in the example of FIG. 10B, the buried shielding structure 240 may laterally extend from a contact shielding structure 140c to under the bottom of the gate trench 180 at one side of the gate trench. The other side of the gate trench 180 (and the associated electrical conduction path 178 along the sidewall thereof and in the vertical direction) may be free of the buried shielding structure 240. In the example of FIG. 10C, the buried shielding structure 240 may laterally extend from respective contact shielding structure 140c to under the bottom of the gate trench 180 at opposing sides of the gate trench, but includes gaps or openings under the gate trench 180 to allow current flow in the vertical direction. Electrical conduction in the lateral direction (i.e., a lateral conduction path into or out of the page in the cross sectional views of FIGS. 8C, 9C, and 10C) may also be provided in a portion 175 of the drift region 120 (e.g., the JFET region 175) between the bottom of the gate trench 180 and the buried shielding structure 240. That is, the buried shielding structure 240 defined by the patterns 840, 940, 1040 may have one or more dimensions (in the lateral or vertical directions) that allow for lateral conduction around the relatively narrow segments 245 thereof to the drain contact 192, as similarly described above with reference to FIG. 3B, 4B, or 5B.

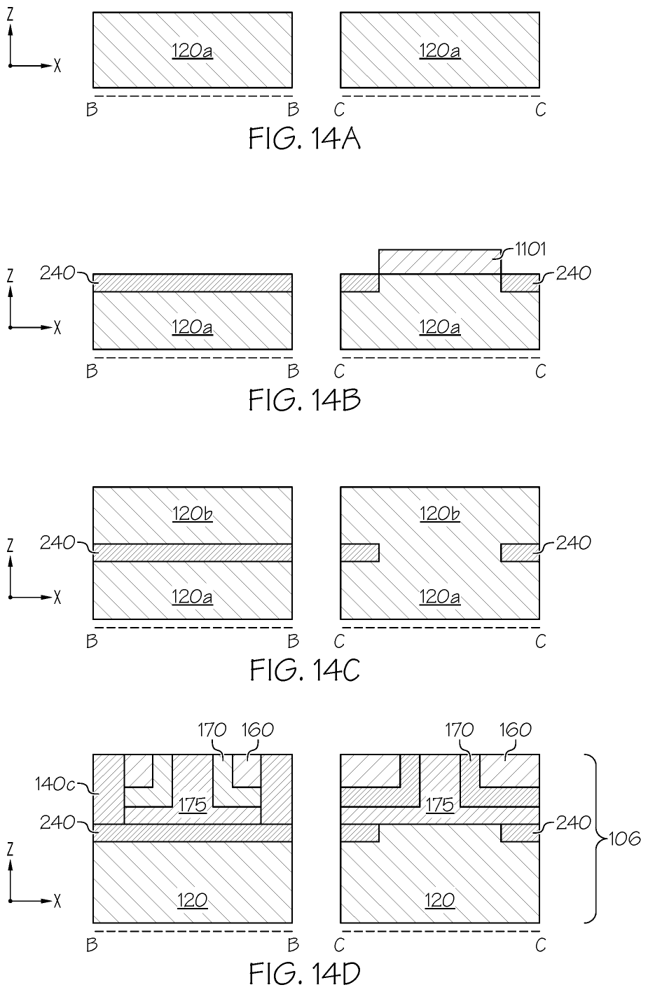

FIGS. 11A-11E, 12A-12F, 13A-13E, 14A-14D, and 15A-15D illustrate various examples of methods of fabricating semiconductor devices including buried shielding structures 240 according to some embodiments of the present disclosure. In FIGS. 11A to 15D, methods of fabricating a semiconductor device include providing a drift region 120 of a first conductivity type, providing a buried shielding structure 240 of a second conductivity type in the drift region 120, and providing a well region 170 of the second conductivity type above the drift region 120 and separated from the buried shielding structure 240. The buried shielding structure 240 may be formed using selective epitaxy, ion implantation, etching, and/or combinations thereof. The buried shielding structure 240 may be formed in various patterns having one or more segments 245 that laterally extend in the drift region 120. While not illustrated, a gate 184 is provided on the semiconductor layer structure 106 adjacent the well region 170 (e.g., in the gate trench 180 in the device of FIG. 11A-13E or 15A-15D or on the surface S in the planar gate device of FIGS. 14A-14D).

In particular, FIGS. 11A-11E are cross sectional views taken along line B-B (illustrating lateral conduction areas) and along line C-C (illustrating vertical conduction areas) of the gate trench structure of FIG. 3A, which illustrate methods of fabricating power semiconductor devices including buried shielding structures according to some embodiments of the present disclosure. As shown in FIG. 11A, a first portion of a drift region 120 having a first (e.g., n−) conductivity type is formed, for example, by a first epitaxy process. In FIG. 11B, a buried shielding structure 240 having a second (e.g., p−) conductivity type is formed in or on the first portion 120a of the drift region 120. In particular, a mask pattern 1101 is formed on the first portion 120a of the drift region 120. For example, a patterning layer may be formed on a mask layer, and the mask layer may be patterned (e.g., photolithographically) using the patterning layer to form a mask pattern 1101 including openings therein exposing portions of the drift region 120, with comparatively greater portions exposed in the lateral conduction areas (along line B-B) than in the vertical conduction areas (along line C-C).

The buried shielding structure 240 may be formed in a desired pattern (such as, but not limited to, the patterns 340, 440, 540, 840, 940, 1040 described herein) based on the areas of the drift region 120 that are exposed by the mask pattern 1101. In some embodiments, one or more ion implantation processes may be performed to selectively implant dopants of the second conductivity type (e.g., p-type) into the areas of the drift region 120 exposed by the mask pattern 1101 to form the buried shielding structure 240 in the desired pattern, using the mask pattern 1101 as an implantation mask. The dopant concentration of the buried shielding structure 240 may be substantially uniform or graded (e.g., stepwise or continuous).

In FIG. 11C, the mask pattern 1101 is removed, and a second portion 120b of the drift region 120 having the first conductivity type is formed on the buried shielding structure 240 (e.g., by a second epitaxy process). In FIG. 11D, a JFET region 175 of the first conductivity type, a well region 170 of the second conductivity type, and a source region 160 of the first conductivity type are formed in or on the second portion 120b of the drift region 120. For example, the JFET region 175, the well region 170, and the source region 160 may be formed in the second portion 120b of the drift region 120 by respective masking and/or ion implantation processes. In some embodiments, additional shallow contact structures 174 of the second conductivity type (e.g., P+ regions) may be formed adjacent the source region 160 to provide electrical contact to the well region 170 170. A semiconductor layer structure 106 including the drift region 120, well region 170, and source region 160 is thereby provided.

As shown in FIG. 11E, contact shielding structures 140c and gate trenches 180 are formed extending into a surface S of the semiconductor layer structure 106. For example, an etching process may be performed to selectively etch portions of the surface S exposed by an etching mask pattern 1101 (not shown) to form gate trenches 180 extending into the drift region 120 120 between and spaced apart from the contact shielding structures 140c.

In FIG. 11E, the contact shielding structures 140c may be formed using various fabrication operations, before (pre-trench) or after (post-trench) forming the gate trenches 180. For example, in some embodiments, an implant mask (not shown) including openings therein exposing portions of the surface S of the semiconductor layer structure 106 may be formed, and one or more ion implantation processes may be performed to implant dopants of the second conductivity type (e.g., p-type) into the exposed portions of the surface to form the contact shielding structures 140c extending into the drift region 120 toward the underlying substrate (e.g., 110). A dose and/or implantation energy of the implantation process(es) may be controlled to form the contact shielding structures 140c with desired dopant concentrations and/or depths (e.g., D1) relative to the surface S (e.g., with higher implantation energies resulting in greater depths). The dopant concentrations of the contact shielding structures 140c may be substantially uniform or graded, and may differ from the dopant concentrations of the well regions 170.

In other embodiments, the contact shielding structures 140c may be formed by forming an etch mask (not shown) including openings therein exposing portions of the surface S of the semiconductor layer structure 106, and performing one or more etching processes may be performed to form shield trenches extending into the exposed portions of the surface S with the desired depths (e.g., D1). One or more deposition processes may be performed to form a material of the second conductivity type (e.g., p-type) in the shield trenches, thereby forming the contact shielding structures 140c of a different material than the drift region 120 (also referred to herein as heterojunction shielding structures) extending into the drift region 120 toward the underlying substrate (e.g., 110). For example, the drift region 120 may be formed of an n-type material (e.g., SiC), and the contact shielding structures 140c may be formed of one or more p-type materials (e.g., p-NiO, p-poly-Si, p-GaN, p-Ga₂O₃).

In some embodiments, a bottom shielding structure (e.g., 140a) may be formed under and at least partially along a bottom surface of the gate trench, either before forming the gate trench 180 (e.g., in the same pre-trench process as forming the buried shielding structure 240) or after forming the gate trench 180 (e.g., using a low-energy post-trench implantation process) in some embodiments. As such, the bottom shielding structures 140a may be implanted regions of (and thus, may include the same material as) the drift region 120, while the buried shielding structure 240 may be formed of a different material than the drift region 120, or vice versa. That is, when present, the bottom shielding structure 140a and the buried shielding structure 240 may be formed using the same or different fabrication operations (e.g., the same or different ion implantation or epitaxial processes), and thus, may be the same as or may differ from one another (e.g., in materials, depth of extension toward the substrate 110, and/or dopant concentration), depending on the fabrication processes used. Likewise, the contact shielding structures 140c may have different depths, dopant concentrations, and/or materials than the bottom shielding structures 140a or the buried shielding structure 240. For example, the contact shielding structures 140c may be formed with similar or higher dopant concentration (for example, 1×10¹⁷ cm⁻³ to 1×10²⁰ cm⁻³) than the bottom shielding structures 140a or the buried shielding structure 240 (for example, 1×10¹⁷ cm⁻³ to 5×10¹⁹ cm⁻³).

Still referring to FIG. 11E, after forming the gate trenches 180, gate insulating layers 182a are formed along sidewalls and bottom surfaces of the gate trenches 180, and gate electrodes 184a are formed in the gate trenches. Source contacts 190 (e.g., ohmic contacts), an intermetal dielectric 186, and a source metal layer 196 may be subsequently formed. The fabrication operations shown in FIGS. 11A-11E may thereby provide the device 200a of FIG. 2A.

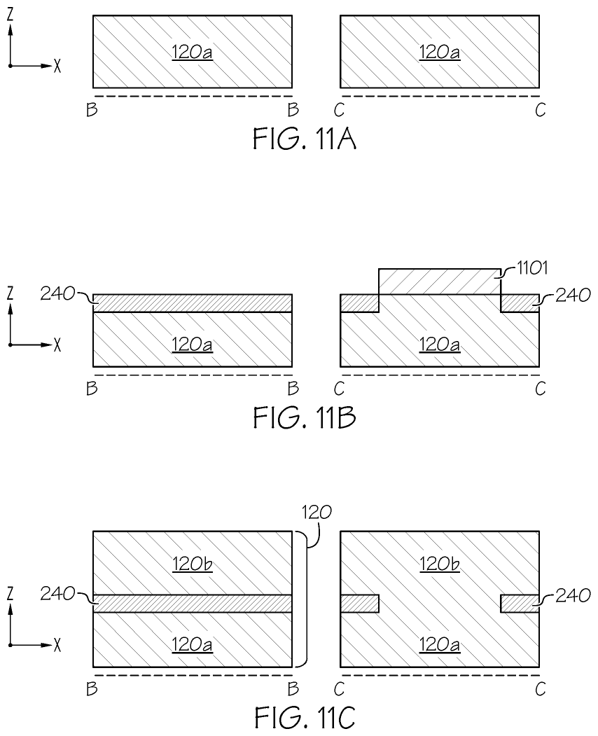

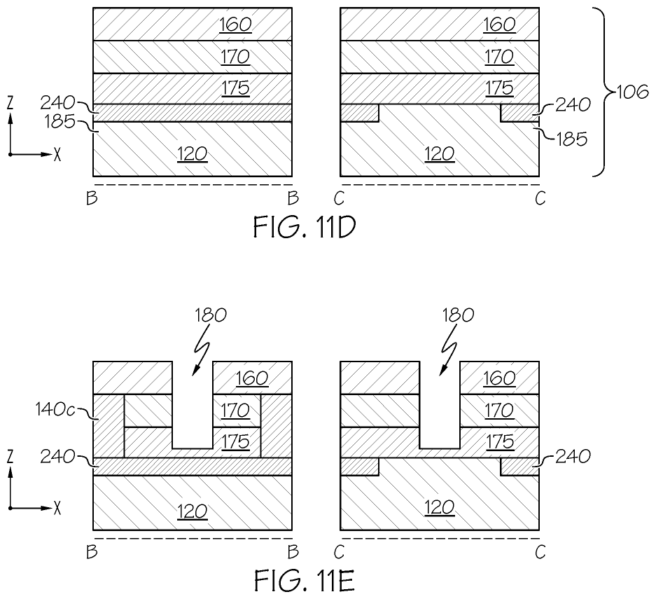

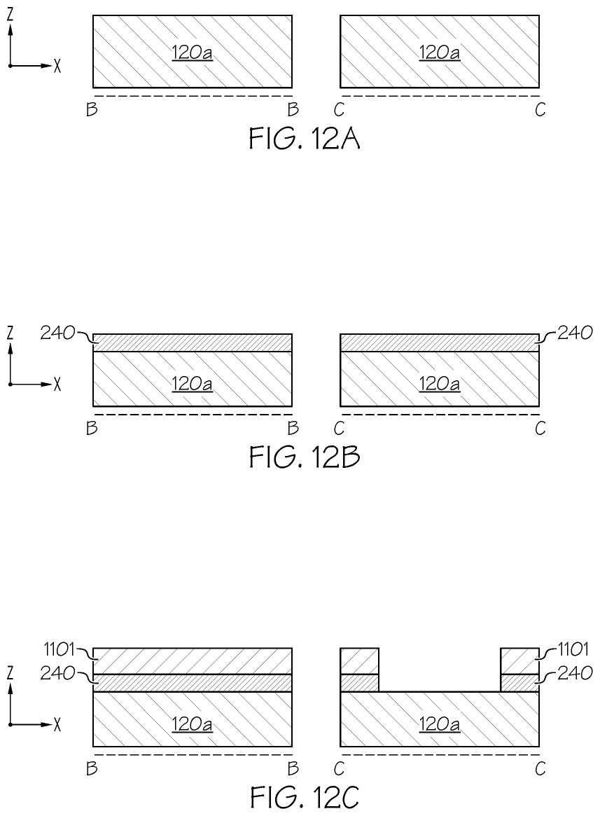

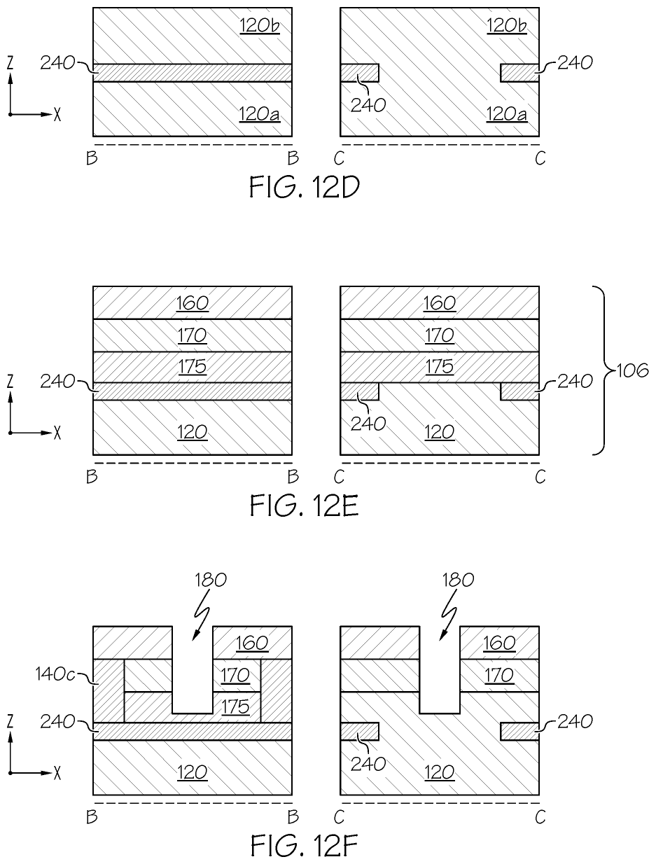

FIGS. 12A-12F are cross sectional views taken along line B-B (illustrating lateral conduction areas) and along line C-C (illustrating vertical conduction areas) of the gate trench structure of FIG. 3A, which illustrate methods of fabricating power semiconductor devices including buried shielding structures according to some embodiments of the present disclosure. The operations of FIGS. 12A-12F may be similar to those of FIGS. 11A-11E, except that the implantation or deposition processes of FIG. 11B are performed as a blanket implantation or epitaxy process without a mask pattern 1101, followed by a subsequent etching process using a mask pattern 1101 to form the buried shielding structure 240 in the desired pattern based on the areas of the drift region 120 that are exposed by the mask pattern 1101.

As shown in FIG. 12A, a first portion of a drift region 120 having a first (e.g., n−) conductivity type is formed, for example, by a first epitaxy process. In FIG. 12B, a buried shielding structure 240 having a second (e.g., p−) conductivity type is formed on the first portion 120a of the drift region 120. In particular, a blanket implantation or epitaxy process is performed to implant or deposit a material of the second conductivity type on the first portion 120a of the drift region 120 to form the buried shielding structure 240. The blanket process may be performed on a majority or entirety of an upper surface of the first portion 120a of the drift region 120.

In FIG. 12C, after the implantation or epitaxy process, a mask pattern 1101 is formed on the first portion 120a of the drift region 120, with openings that expose comparatively greater portions in the lateral conduction areas (along line B-B) than in the vertical conduction areas (along line C-C). An etching process is selectively performed on areas of the first portion 120a of the drift region 120 using the mask pattern 1101 to form the buried shielding structure 240 in the desired pattern based on the areas of the drift region 120 exposed by the mask pattern 1101.

In FIG. 12D, the mask pattern 1101 is removed, and a second portion 120b of the drift region 120 having the first conductivity type is formed on the buried shielding structure 240 (e.g., by a second epitaxy process). In FIG. 12E, a JFET region 175 of the first conductivity type, a well region 170 of the second conductivity type, and a source region 160 of the first conductivity type are formed in or on the second portion 120b of the drift region 120, and in FIG. 12F, contact shielding structures 140c and gate trenches 180 are formed extending into a surface S of the semiconductor layer structure 106, as similarly described above with reference to FIGS. 11A-11E. In some embodiments, bottom shielding structures (e.g., 140a) may be formed under and at least partially along bottom surfaces of the gate trenches. Gate insulating layers 182a, gate electrodes 184a, source contacts 190, intermetal dielectric 186, and metal layer 196 may be subsequently formed to provide the device 200a of FIG. 2A.

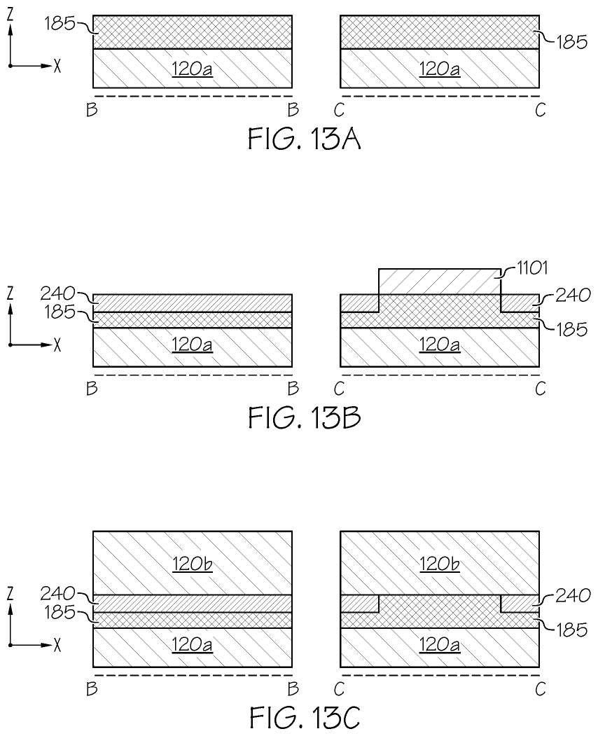

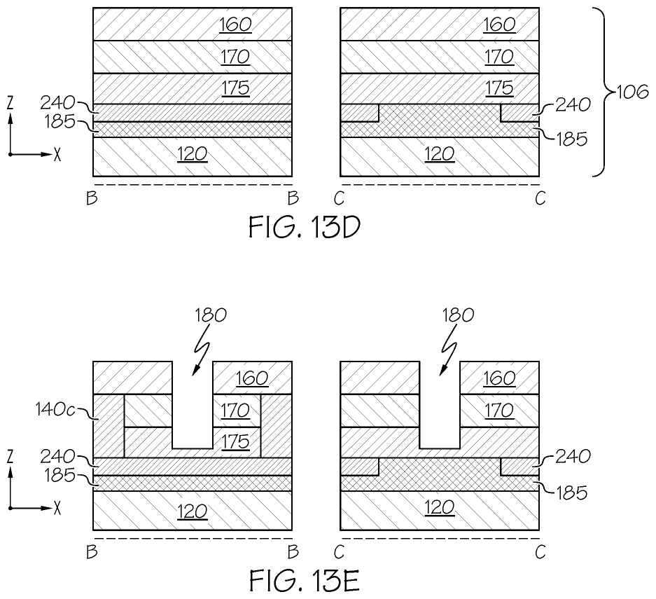

FIGS. 13A-13E are cross sectional views taken along lines B-B and C-C of the gate trench structure of FIG. 3A illustrating methods of fabricating power semiconductor devices including buried shielding structures according to some embodiments of the present disclosure. The operations of FIGS. 13A-13E may be similar to those of FIGS. 11A-11E, except that a current spreading layer or region may be formed above and/or below the buried shielding structure 240.

As shown in FIG. 13A, a first portion of a drift region 120 having a first (e.g., n−) conductivity type is formed (e.g., by a first epitaxy process), and a current spreading region 185 having a greater concentration of dopants of the first conductivity type is formed in the first portion 120a of the drift region 120. For example, the current spreading region 185 may be an N+ region that is implanted into or otherwise formed on the first portion 120a of the drift region 120 using a selective or blanket process.

In FIG. 13B, a buried shielding structure 240 having a second (e.g., p−) conductivity type is formed in or on the first portion 120a of the drift region 120. In particular, a mask pattern 1101 is formed on the first portion 120a of the drift region 120 (e.g., on the current spreading region 185), and the buried shielding structure 240 is formed in a desired pattern based on the areas of the drift region 120 that are exposed by the mask pattern 1101. For example, the buried shielding structure 240 may be formed in or on portions of the current spreading region 185 using one or more ion implantation processes or selective epitaxy processes to implant or deposit material of the second conductivity type (e.g., p-type) into or on the areas exposed by the mask pattern 1101. The current spreading region 185 may thus extend above and/or below the buried shielding structure 240, relative to an underlying substrate (e.g., 110).

In FIG. 13C, the mask pattern 1101 is removed, and a second portion 120b of the drift region 120 having the first conductivity type is formed on the buried shielding structure 240 and/or on the current spreading region 185 (e.g., by a second epitaxy process). In FIG. 13D, a JFET region 175 of the first conductivity type, a well region 170 of the second conductivity type, and a source region 160 of the first conductivity type are formed in or on the second portion 120b of the drift region 120, and in FIG. 13E, contact shielding structures 140c and gate trenches 180 are formed extending into a surface S of the semiconductor layer structure 106, as similarly described above with reference to FIGS. 11A-11E.

The gate trenches 180 may be confined above the current spreading region 185 in some embodiments. In some embodiments, bottom shielding structures (e.g., 140a) may be formed under and at least partially along bottom surfaces of the gate trenches. Gate insulating layers 182a, gate electrodes 184a, source contacts 190, intermetal dielectric 186, and metal layer 196 may be subsequently formed to provide the device 200a of FIG. 2A.

FIGS. 14A-14D are cross sectional views taken along lines B-B and C-C of the planar gate structure of FIG. 3A illustrating methods of fabricating power semiconductor devices including buried shielding structures according to some embodiments of the present disclosure. The operations of FIGS. 14A-14D may be similar to those of FIGS. 11A-11E, except that the device is formed with a planar gate structure.

As shown in FIG. 14A, a first portion of a drift region 120 having a first (e.g., n−) conductivity type is formed (e.g., by a first epitaxy process). In FIG. 14B, a buried shielding structure 240 having a second (e.g., p−) conductivity type is formed in or on the first portion 120a of the drift region 120. In particular, a mask pattern 1101 is formed on the first portion 120a of the drift region 120, and the buried shielding structure 240 is formed in a desired pattern, for example, using one or more ion implantation processes or selective epitaxy processes to implant or deposit material of the second conductivity type into or on the areas exposed by the mask pattern 1101.

In FIG. 14C, the mask pattern 1101 is removed, and a second portion 120b of the drift region 120 having the first conductivity type is formed on the buried shielding structure 240 (e.g., by a second epitaxy process). In FIG. 14D, a JFET region 175 of the first conductivity type, well regions 170 of the second conductivity type, and source regions 160 of the first conductivity type are formed in or on the second portion 120b of the drift region 120, and contact shielding structures 140c are formed extending into a surface S of the semiconductor layer structure 106. Gate insulating layers 182b, gate electrodes 184b, source contacts 190, intermetal dielectric 186, and metal layer 196 may be subsequently formed to provide the device 200b of FIG. 2B.

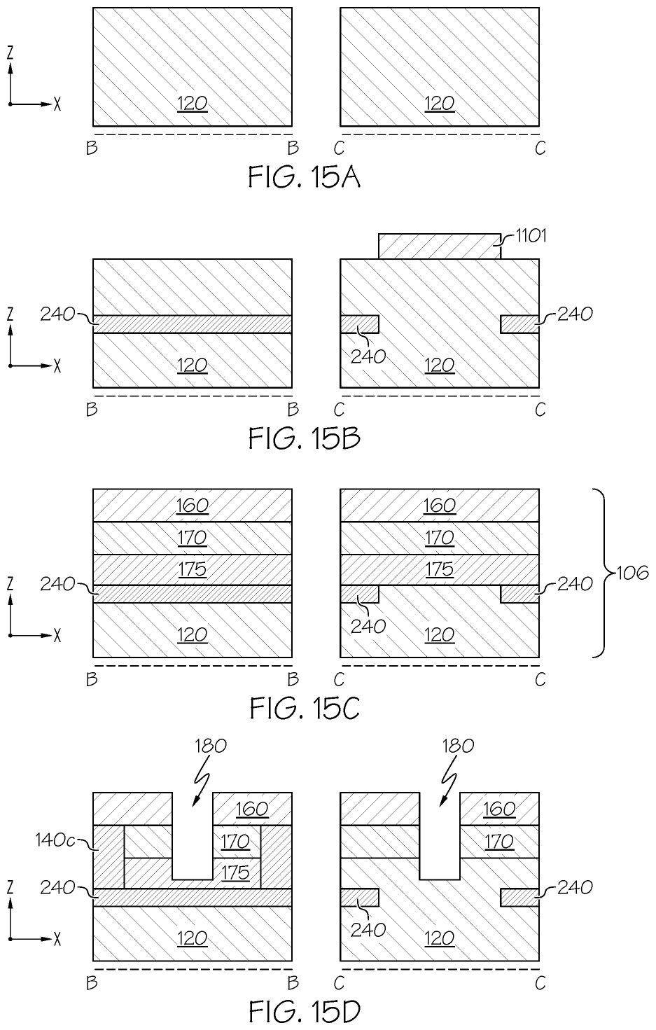

FIGS. 15A, 15B, 15C, and 15D are cross sectional views taken along lines B-B and C-C of the gate trench structure of FIG. 3A illustrating methods of fabricating power semiconductor devices including buried shielding structures according to some embodiments of the present disclosure. The operations of FIGS. 15A-15D may be similar to those of FIGS. 11A-11E, except that the buried shielding structure 240 is formed by one or more deep ion plantation processes.

As shown in FIG. 15A, a drift region 120 having a first (e.g., n−) conductivity type is formed (e.g., by an epitaxy process). In contrast to the embodiments discussed above, the drift region 120 may be formed to a desired thickness (e.g., the thickness of the semiconductor layer structure 106 in the completed device) prior to forming the buried shielding structure 240.

In FIG. 15B, the buried shielding structure 240 having a second (e.g., p−) conductivity type is formed in the drift region 120 at a desired depth (e.g., D1) relative to a surface S thereof. In particular, a mask pattern 1101 is formed on the surface S of the drift region 120, and the buried shielding structure 240 is formed in a desired pattern using one or more deep ion implantation processes to implant dopant material of the second conductivity type into the areas exposed by the mask pattern 1101. A dose and/or implantation energy of the implantation process(es) may be controlled to form the buried shielding structure 240 with predetermined dopant concentrations and/or depths (e.g., D1) below the surface S (e.g., with higher implantation energies resulting in greater depths).

In FIG. 15C, the mask pattern 1101 is removed, and a JFET region 175 of the first conductivity type, well region 170 of the second conductivity type, and source region 160 of the first conductivity type are formed in or on the second portion 120b of the drift region 120. In FIG. 15D, contact shielding structures 140c and gate trenches 180 are formed extending into a surface S of the semiconductor layer structure 106, as similarly described above with reference to FIGS. 11A-11E. Gate insulating layers 182b, gate electrodes 184b, source contacts 190, intermetal dielectric 186, and metal layer 196 may be subsequently formed to provide the device 200b of FIG. 2B.

Referring again to FIGS. 2A and 2B, after the operations shown in FIGS. 11E, 12F, 13E, 14D, and 15D, a drain contact 192 is provided on the substrate 110 opposite the drift region 120. As such, the buried shielding structure 240 laterally extends in the drift region 120 between the well region 170 and the drain contact 192. In some embodiments, the gate 184 may provide a first gate G1 of a first transistor TX1 in the semiconductor layer structure 106, and the buried shielding structure 240 may provide a second gate G2 of a second transistor TX2 in the semiconductor layer structure 106, such that the first and second transistors TX1, TX2 are electrically coupled in a cascode amplifier configuration 700.

It will be understood that any of the operations shown in FIGS. 11A to 15D may be combined in various embodiments herein. For example, one or more of pre-trench implant operations may be performed between one or more of the pre-trench heterojunction operations, or vice versa. Likewise, one or more of the post-trench implant operations may be performed between one or more of the post-trench heterojunction operations, or vice versa. More generally, the fabrication operations shown in FIGS. 11A to 15D are illustrated by way of example with reference to forming the shielding regions 140a, 140c, 240 by implantation or epitaxial growth or deposition, but it will be understood that any of the operations shown may be utilized in combination to provide any desired combination of implanted and heterojunction shielding regions 140a, 140c, 240, with similar or different depths and/or materials from one another.

As described above, the contact shielding structures 140c may have various shapes, including island-shapes (see, for example, FIG. 3A) or stripe-shapes (see, for example, FIG. 10A) in plan view. As further described herein, the contact shielding structure(s) 140c may include or refer to both (i) support shielding structures and (ii) bridge shielding structures. The support shielding structures may reduce electric field levels in the gate oxide layers during device operation, and/or may provide a low-resistance current path between the source and drain terminals of the MOSFET if avalanche breakdown occurs. The bridge shielding structures may electrically connect the bottom shielding structures 140a to the support shielding structures. In some embodiments, the contact shielding structures 140c (including the support shielding structures and/or the bridge shielding structures) may be discontinuous or segmented, providing additional area in the semiconductor structure for current flow.

In particular, the contact shielding structures 140c may include a plurality of discrete segments that extend longitudinally (e.g., lengthwise) in one or more lateral directions (e.g., in the X-direction, the Y-direction, or other directions in the X-Y plane), and may have respective segments widths along a direction crossing the respective longitudinal directions of extension. Spacings between segments of the contact shielding structures 140c (e.g., along the respective longitudinal directions of extension of the segments) may be sufficient to avoid punch-through (e.g., at the well regions) or otherwise avoid premature breakdown of the devices. As such, segmented contact shielding structures as further described herein may provide similar blocking capabilities in comparison to continuously extending contact shielding structures, while reducing on-resistance (Rds, on) for a given area of a device.

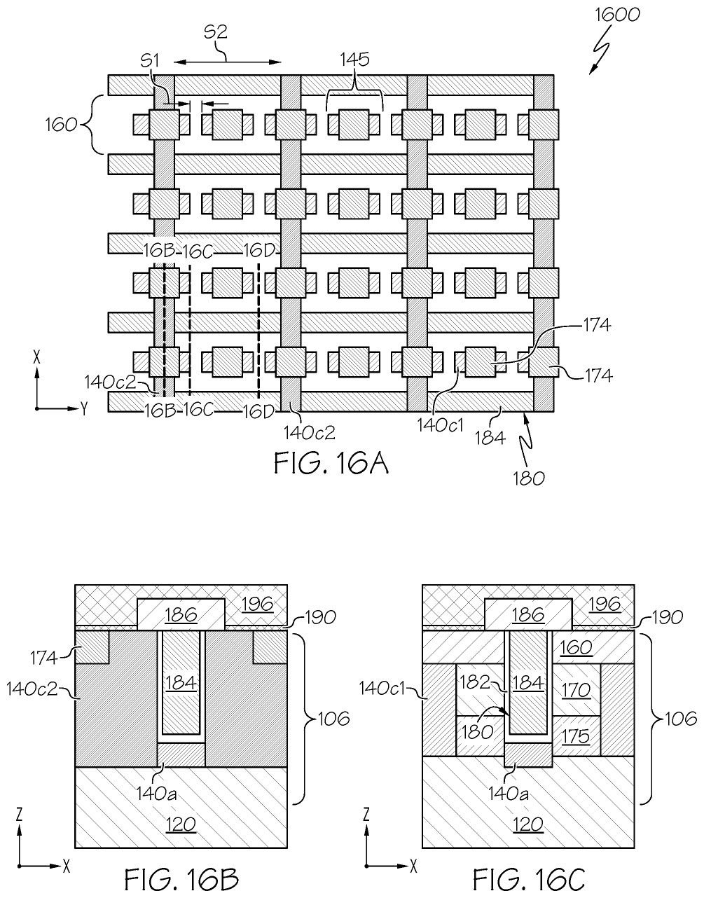

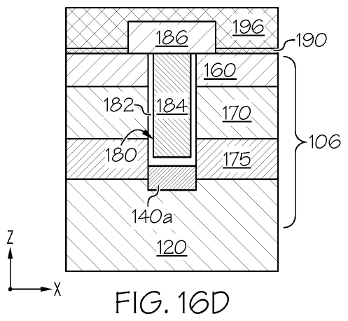

The spacings between the segments of the contact shielding structures 140c can differ in various embodiments so as to improve or optimize performance. For example, providing more segments of the contact shielding structures 140c may improve avalanche capabilities (by providing the shielding patterns with greater peripheral area to distribute avalanche current), but increasing the number of contact shielding structures 140c may increase device on-resistance (due to reduction of the available active area in the semiconductor structure). Embodiments of the contact shielding structures 140c described below with reference to FIGS. 16-22 may be used alone or in combination with any of the buried shielding structures (e.g., 240) or associated patterns (e.g., 340, 440, etc.) described herein with reference to FIGS. 1-15.

FIGS. 16A, 17A, 18A, and 19A are plan views illustrating semiconductor devices 1600 1700, 1800, and 1900 including example contact shielding structures 140c and gate electrodes 184 extending in gate trenches 180 according to some embodiments of the present disclosure. As shown in FIGS. 16A, 17A, 18A, and 19A, the gates 184 continuously extend in one lateral direction (shown in these examples as the Y-direction), while the contact shielding structure 140c discontinuously extends in one or more lateral directions (e.g., one or more directions in the X-Y plane). More particularly, the contact shielding structure 140c includes support shielding structures 140c1 and bridge shielding structures 140c2, at least one of which discontinuously extends in one or more lateral directions (shown in these examples as the Y-direction for the support shielding structures 140c1 and the X-direction for the bridge shielding structures 140c2). The support shielding structures 140c1 longitudinally extend in a first lateral direction (shown as the Y-direction), parallel to and spaced apart from the gates 184. The bridge shielding structures 140c2 extend in a second lateral direction, which crosses the first lateral direction, towards the gates 184 (e.g. to contact the bottom shielding structures 140a under the gates 184).

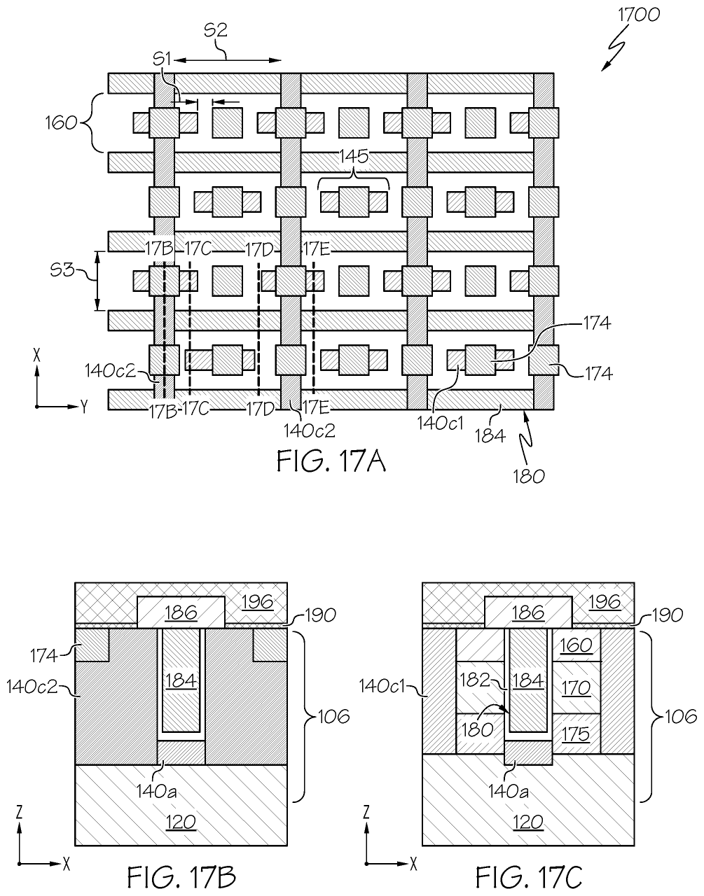

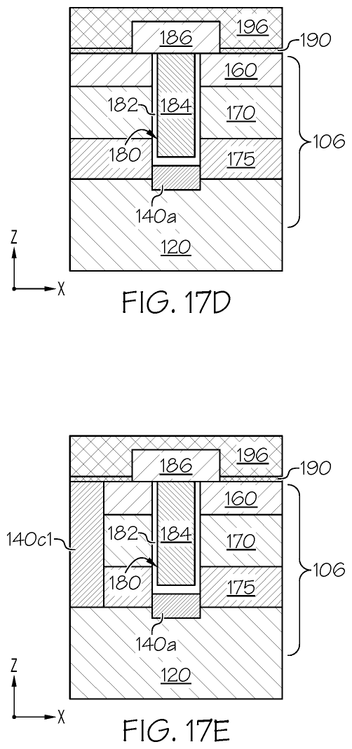

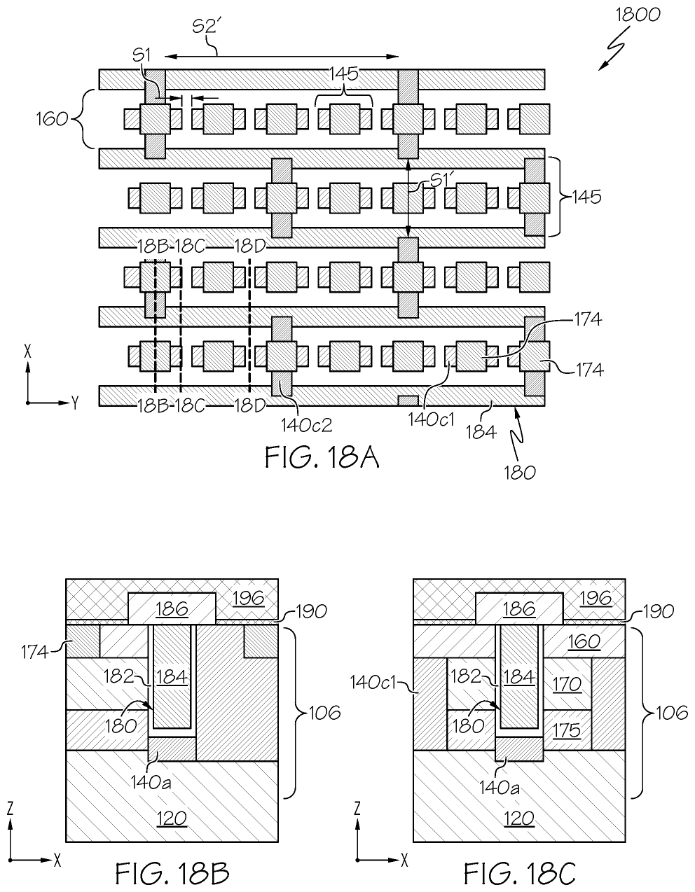

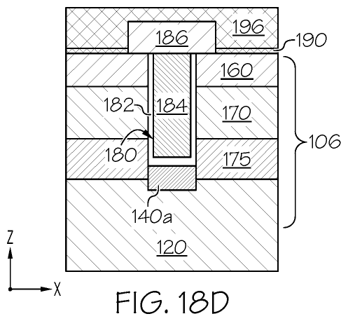

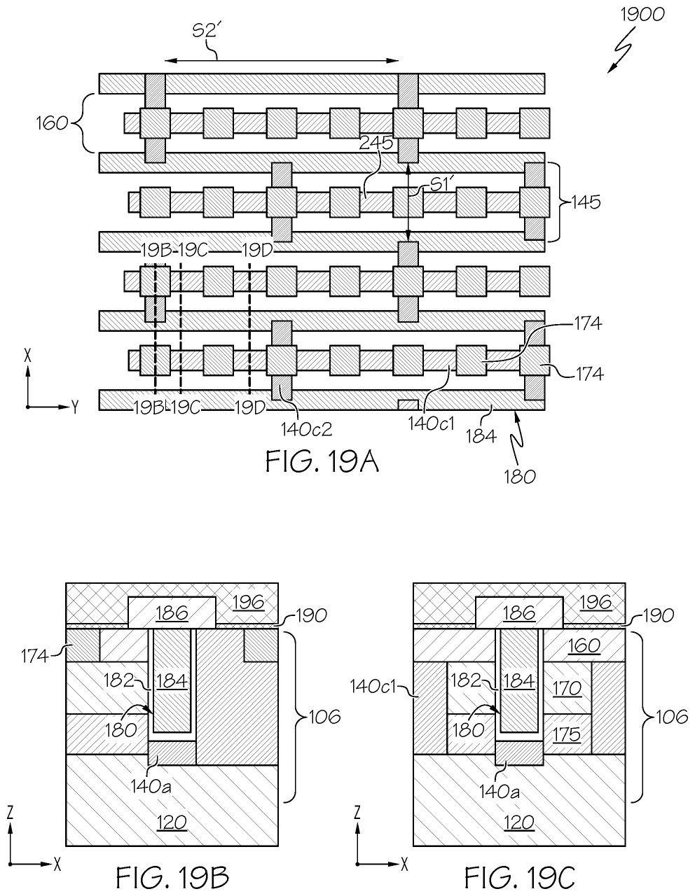

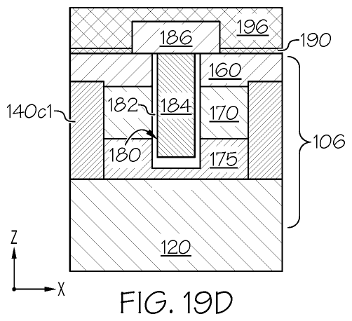

The contact shielding structure 140c (including the support shielding structures 140c1 and/or the bridge shielding structures 140c2) may include a plurality of discrete segments 145 that longitudinally extend in one or more lateral directions. For example, as shown in FIGS. 16A and 17A, the support shielding structures 140c1 include segments 145 with spacings S1 therebetween along the Y-direction, while the bridge shielding structures 140c2 continuously extend along the X-direction. The spacings S1 between segments 145 of the support shielding structures 140c1 are aligned along the X-direction in the example device 1600 of FIG. 16A, while the spacings S1 between segments 145 of the support shielding structures 140c1 are staggered along the X-direction in the example device 1700 of in FIG. 17A. In the example device 1800 of FIG. 18A, spacings S1 are provided between the segments 145 of the support shielding structures 140c1 along the Y-direction, and spacings S1′ are provided between the segments 145 of the bridge shielding structures 140c2 along the X-direction. In the example device 1900 of FIG. 19A, spacings S1′ are provided between the segments 145 of the bridge shielding structures 140c2 along the X-direction, while the support shielding structures 140c1 continuously extend along the Y-direction.

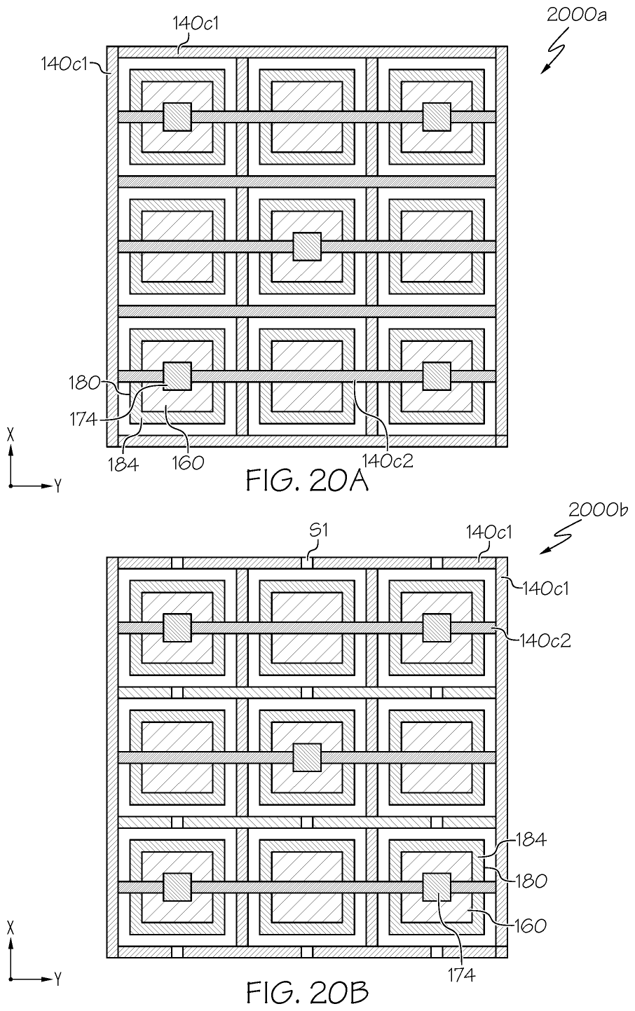

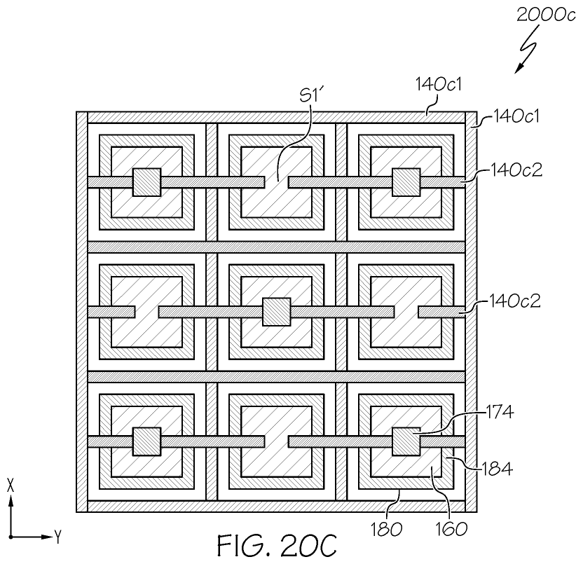

FIGS. 20A, 20B, and 20C are plan views illustrating semiconductor devices 2000a, 2000b, and 2000c including alternative arrangements of contact shielding structures 140c in combination with square-shaped trenched gate electrodes 184. In particular, as shown in the example device 2000a of FIG. 20A, the support shielding structures 140c1 laterally extend in both the X- and Y-directions, parallel to and spaced apart from respective sidewalls of the square-shaped gate trenches 180. The bridge shielding structures 140c2 laterally extend in the Y-direction, intersecting and extending along opposing sidewalls of respective gate trenches 180. In the example device 2000b of FIG. 20B, the support shielding structures 140c1 include segments 145 with spacings S1 therebetween along the Y-direction (as shown) and/or along the X-direction, while the bridge shielding structures 140c2 continuously extend along the Y-direction. In the example device 2000c of FIG. 20C, spacings S1′ are provided between the segments 145 of the bridge shielding structures 140c2 along the Y-direction, while the support shielding structures 140c1 continuously extend in both the X- and Y-directions.

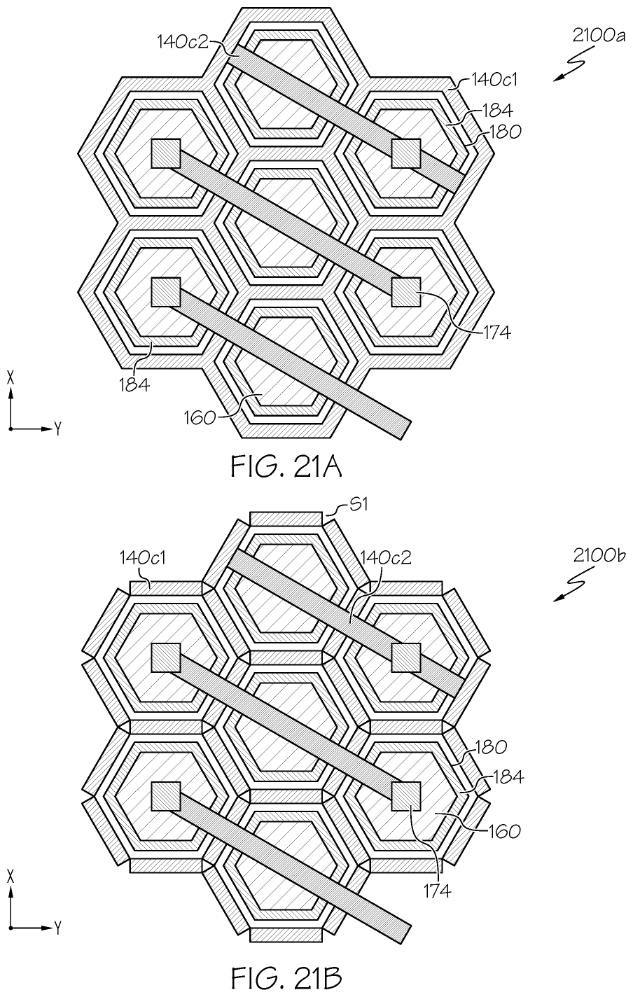

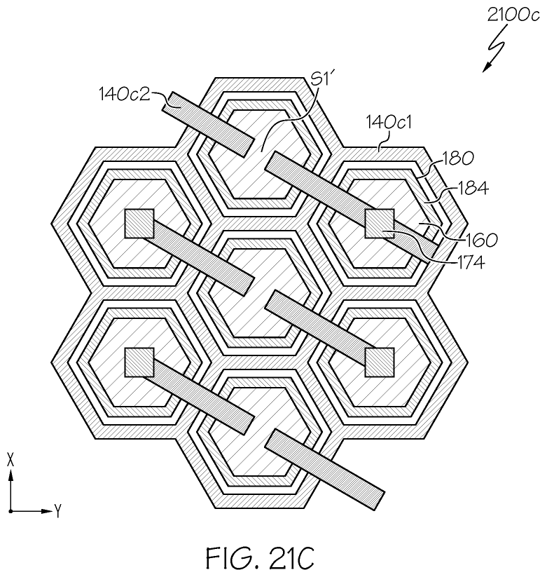

FIGS. 21A, 21B, and 21C are plan views illustrating semiconductor devices 2100a, 2100b, and 2100c including further alternative arrangements of contact shielding structures 140c in combination with hexagonal-shaped trenched gate electrodes 184. In particular, as shown in the example device 2100a of FIG. 21A, the support shielding structures 140c1 laterally extend in multiple directions in the X-Y plane, parallel to and spaced apart from respective sidewalls of the hexagonal-shaped gate trenches 180. The bridge shielding structures 140c2 laterally extend in one direction in the X-Y plane, intersecting and extending along opposing sidewalls of respective gate trenches 180. In the example device 2100b of FIG. 21B, the support shielding structures 140c1 include segments 145 with spacings S1 therebetween, while the bridge shielding structures 140c2 continuously extend in the illustrated lateral direction. In the example device 2100c of FIG. 21C, spacings S1′ are provided between the segments 145 of the bridge shielding structures 140c2 in the illustrated lateral direction, while the support shielding structures 140c1 continuously extend in multiple directions in the X-Y plane around the sidewalls of the hexagonal-shaped gate trenches 180.

The plan views of FIGS. 16A, 17A, 18A, 19A, 20A-20C, and 21A-21C discussed above are provided by way of example only, and it will be understood that embodiments of the present disclosure are in no way limited to the arrangements or patterns shown in the examples described herein. That is, embodiments of the present disclosure may include any contact shielding structures 140c having support shielding structures 140c1 that are discontinuous or segmented in one or more lateral directions and bridge shielding structures 140c2 that are continuous in one or more lateral directions (or vice versa), as well as combinations thereof, with linear, elliptical, or polygonal shapes in plan view.

FIGS. 16B-16D, 17B-17E, 18B-18D, and 19B-19D illustrate various cross-sections of the semiconductor devices 1600, 1700, 1800, and 1900, respectively. As shown in these cross-sectional views, the semiconductor layer structure 106 includes a drift region 120 of a first conductivity type and a well region 170 of a second conductivity type in or above the drift region. The drift region 120 may also include an (optional) current spreading layer of the first conductivity type below the well region 170 in some embodiments. A gate trench 180 having opposing sidewalls and a bottom surface therebetween vertically extends through the well regions and into the drift region 120, with a gate insulating layer 182 and gate 184 extending between sidewalls of the gate trench 180. A portion 175 of the drift region under the well region 170 and the bottom of the gate trench 180 may be referred to as the JFET region 175. A contact shielding structure 140c of the second conductivity type includes support shielding structures 140c1 and bridge shielding structures 140c2 that vertically extend from the well region 170 into the drift region 120, and discontinuously extend in one or more lateral directions.

In particular, FIGS. 16C, 17C, 17E, 18C, 19C, and 19D illustrate cross-sections of example support shielding structures 140c1. The support shielding structures 140c1 longitudinally extend in a first lateral direction (shown as the Y-direction) and are spaced apart from respective gates 184 in a second lateral direction (shown as the X-direction). In the cross-sections shown in FIGS. 16C, 17C, 18C, 19C and 19D, the support shielding structures 140c1 are spaced apart from both opposing sidewalls of the respective gate trenches 180. In the cross-section shown in FIG. 17E, the support shielding structure 140c1 is segmented so as to be spaced apart from only one of the sidewalls of the gate trench 180 (with no support shielding structure 140c1 adjacent the opposing sidewall of the gate trench 180). As noted above, the support shielding structures 140c1 may be configured to reduce electric field concentration in the gate insulating layers 182 during device operation. The support shielding structures 140c1 may also provide a low-resistance current path between the source and drain terminals of the devices 1600, 1700, 1800, 1900 in case of avalanche breakdown.

FIGS. 16B, 17B, 18B, and 19B illustrate cross-sections of example bridge shielding structures 140c2. The bridge shielding structures 140c2 longitudinally extend towards the gates 184 in a lateral direction (shown as the X-direction) that crosses the direction of extension of the support shielding structures 140c1 (shown as the Y-direction). As noted above, the bridge shielding structures 140c2 may be configured to electrically connect the support shielding structures 140c1 to a bottom shielding structure 140a that extends (continuously or discontinuously) under the bottom surface of the gate trench 180 to reduce or prevent electric field breakdown of the gate insulating layer 182, particularly at corners of the gate trench 180. The bridge shielding structure 140c2 may extend on one or both sidewalls of a respective gate trench 180 (i.e., forming a one-sided or two-sided “bridge” that contacts the bottom shielding structure 140a). The cross-sections shown in FIGS. 16B and 17B illustrate the two-sided bridge shielding structure 140c2 extending along both of the opposing sidewalls of the gate trench 180 to contact the bottom shielding structure 140a. The cross-sections shown in FIGS. 18B and 19B illustrate the one-sided bridge shielding structure 140c2, which is segmented so as to extend along only one of the sidewalls of the gate trench 180 to contact the bottom shielding structure 140a, thereby allowing conduction along the opposing sidewall of the gate trench 180 (which is free of the bridge shielding structure 140c2).

In either the one-sided or two-sided bridge configurations, the bridge shielding structures 140c2 electrically couple the bottom shielding structure 140a to heavily-doped regions 174 and source contacts 190 on a surface of the semiconductor layer structure 106. In particular, a source region 160 of the first conductivity type and a heavily-doped region 174 of the second conductivity type is provided above the well region 170, and the source contact 190 is electrically coupled to the source region 160 and the heavily-doped region 174 at the surface of the semiconductor layer structure 106. An intermetal dielectric layer 186 separates the gate 184 from metal layer(s) 196 formed to contact the source contacts 190. The bridge shielding structures 140c2 (or segments 145 thereof) vertically extend from the source contact 190 to the bottom shielding structure 140a, and laterally extend from the bottom shielding structure 140a to contact the support shielding structures 140c1 (or segments 145 thereof), to provide electrical connection to the source contact 190, which is electrically coupled to the source region 160 at the top surface of the semiconductor structure 106 (e.g., opposite the drain contact 192 in FIG. 2A).

As shown in the cross-sections of FIGS. 16D, 17D, 18D, and 19D, the segments 145 of the support shielding structures 140c1 and/or the bridge shielding structures 140c2 in accordance with embodiments described herein are configured so as to provide the above advantages with respect to electric field concentration and avalanche performance while also increasing or maximizing the area of the semiconductor layer structure 106 that is available for conduction. In particular, the segments 145 of the support shielding structures 140c1 and/or the bridge shielding structures 140c2 are laterally spaced apart (by spacings S1, S1′) to define a relatively sparse pattern such that the contact shielding structure 140c is absent in portions of the semiconductor structure 106. That is, the respective spacings S1, S1′ between the discrete segments 145 may include portions of the drift region 120 between the well region 170 and the drain contact (not shown) that are free of the contact shielding structure 140c. In some embodiments, the spacings S1, S1′ between segments 145 (and/or the spacings S2, S2′ between adjacent bridge shielding structures 140c2) may be provided such that fewer than one bridge shielding structure 140c2 is included in each transistor unit cell, thereby increasing the available conduction area in the semiconductor layer structure 106.

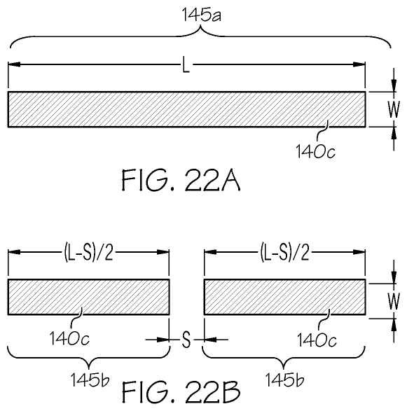

FIGS. 22A and 22B are plan views illustrating example segments 145a, 145b and spacings S1, S1′ of contact shielding structures 140c according to some embodiments of the present disclosure. The segments 145a, 145b (collectively 145) shown in FIGS. 22A and 22B may represent segments of any of the support shielding structures 140c1 or bridge shielding structures 140c2 (collectively 140c) described herein. The dimensions L, W of the segments 145 and/or the spacings S therebetween may be configured to increase avalanche breakdown performance.

As shown in FIG. 22A, the segment 145a of the contact shielding structure 140c longitudinally extends along a length L and has a width W along a direction crossing or perpendicular to the length L. A total peripheral area of the segment 145a is thus 2L+2W. As described above, avalanche performance may be improved by configuring the contact shielding patterns 140c to provide greater peripheral area for distribution of avalanche current. The peripheral area of the contact shielding structure 140c may thereby be increased by increasing the number of segments 145. In particular, as shown in FIG. 22B, two segments 145b of the contact shielding structure 140c longitudinally extend along the same length L and width W as the segment 145a of FIG. 22A, with a spacing S between the segments 145b. The total peripheral area of the segments 145b is thus 4(L−S)/2+4W=2L−2S+4W, which is greater than the peripheral area of (and thus allows for improved avalanche performance relative to) the segment 145a. The respective widths W of the segments 145b being greater than the spacings S between the segments 145b may increase peripheral area (and in particular, the corner area or number of corners) for avalanche current distribution. Stated another way, improved avalanche performance may be achieved when the respective spacings S between the discrete segments 145b are less than respective widths W of the discrete segments 145b. In some embodiments, the respective widths of the discrete segments may be between about 0.1 to 20 microns, for example, about 0.1 to 10 microns). However, as also noted above, providing more segments 145 of the contact shielding structure 140c may improve avalanche capabilities at the expense of on-resistance Rds,on. In some embodiments, semiconductor devices including segmented contact shielding structures 140c (i.e., with spacings between support shielding structures 140c1 and/or bridge shielding structures 140c2) as described herein may be configured to provide avalanche capability that is increased by greater than about 5% (for example, by about 5% to about 30%) in comparison with devices having a continuously extending (i.e., non-segmented) shielding structure, with an on-resistance that is reduced by more than 5% (for example, by about 5% to about 30%) in comparison with devices having a continuously extending shielding structure.

The examples of FIGS. 16-22 are described with reference to trenched gate configurations where the gates 184 are provided in respective gate trenches 180 that include opposing sidewalls and a bottom surface therebetween extending into the drift region 120. However, embodiments of the present disclosure are not limited to such gate configurations, and may include planar gate configurations (e.g., as shown in FIG. 2B) as well. The bottom shielding structures 140a may continuously extend under the gates 184, or may include one or more discrete segments that extend under the gates 184. The bottom shielding structures 140a and/or the gates 184/trenches 180 may have linear, elliptical, or polygonal shapes in plan view.

The embodiments described herein thus illustrate various examples of different combinations of shielding structures in accordance with the present disclosure. However, it will be understood that embodiments of the present disclosure may include any and all combinations of the features described herein, and are not limited to the example patterns illustrated. Embodiments of the present invention may be used in trenched or planar gate vertical semiconductor power transistors, including but not limited to MOSFETs, IGBTs, or other power devices where a contact to a shielding region below and/or separated from the well or gate is desired.

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide bandgap semiconductor material system. As an example, gallium nitride based semiconductor materials (e.g., gallium nitride, aluminum gallium nitride, etc.) may be used instead of silicon carbide in any of the embodiments described above. More generally, while discussed with reference to silicon carbide devices, embodiments of the present invention are not so limited, and may have applicability to devices formed using other wide bandgap semiconductor materials, for example, gallium nitride, zinc selenide, or any other II-VI or III-V wide bandgap compound semiconductor materials.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a fabrication operations. It will be appreciated that the steps shown in the fabrication operations need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a semiconductor layer structure comprising a drift region of a first conductivity type and a well region of a second conductivity type above the drift region;
a gate on the semiconductor layer structure adjacent the well region; and
a contact shielding structure of the second conductivity type that vertically extends from the well region into the drift region and discontinuously extends in one or more lateral directions.

2. The semiconductor device of claim 1, wherein the contact shielding structure comprises a plurality of discrete segments that extend in the one or more lateral directions, respectively.

3. The semiconductor device of claim 2, wherein the contact shielding structure comprises support shielding structures that extend in a first lateral direction and are spaced apart from the gate.

4. The semiconductor device of claim 3, further comprising:
a bottom shielding structure of the second conductivity type in the drift region under the gate,
wherein the contact shielding structure further comprises bridge shielding structures that extend in a second lateral direction, which crosses the first lateral direction, to contact the bottom shielding structure.

5. The semiconductor device of claim 4, wherein at least one of the support shielding structures or the bridge shielding structures comprises the discrete segments.

6. The semiconductor device of claim 5, wherein the semiconductor layer structure further comprises:
a gate trench having opposing sidewalls and a bottom surface therebetween extending into the drift region, wherein the gate is in the gate trench,
wherein the bottom shielding structure extends under the bottom surface of the gate trench.

7. The semiconductor device of claim 6, wherein the bridge shielding structures extend along both of the opposing sidewalls of the gate trench.

8. The semiconductor device of claim 6, wherein the bridge shielding structures comprise the discrete segments, wherein one of the opposing sidewalls of the gate trench comprises one of the bridge shielding structures thereon and another of the opposing sidewalls of the gate trench is free of the one of the bridge shielding structures.

9. The semiconductor device of claim 4, wherein the bottom shielding structure continuously extends under the gate.

10. The semiconductor device of claim 4, wherein the bottom shielding structure includes one or more discrete segments that extend under the gate.

11. The semiconductor device of claim 4, further comprising:
a buried shielding structure that extends in one or more lateral directions under the well region and is separated therefrom by a portion of the drift region.

12. The semiconductor device of claim 4, wherein the bottom shielding structure and/or the gate has a linear, elliptical, or polygonal shape in plan view.

13. The semiconductor device of claim 4, wherein at least a part of an electrical conduction path between the well region and a drain contact laterally extends under the bridge shielding structures.

14. The semiconductor device of claim 2, wherein respective spacings between the discrete segments are aligned along a direction crossing the one or more lateral directions.

15. The semiconductor device of claim 2, wherein respective spacings between the discrete segments are staggered along a direction crossing the one or more lateral directions.

16. The semiconductor device of claim 2, wherein respective spacings between the discrete segments are less than respective widths of the discrete segments.

17. The semiconductor device of claim 16, wherein the respective widths of the discrete segments are between about 0.1 and about 20 microns.

18. The semiconductor device of claim 2, wherein the semiconductor layer structure further comprises:
a substrate, wherein the drift region is on the substrate; and
a drain contact on the substrate opposite the drift region,
wherein respective spacings between the discrete segments comprise portions of the semiconductor layer structure that are free of the contact shielding structure.

19. The semiconductor device of claim 18, wherein the semiconductor layer structure further comprises a source region of the first conductivity type above the well region, and further comprising:
a source contact on a surface of the semiconductor layer structure opposite the drain contact, wherein the source contact is electrically coupled to the source region and the contact shielding structure.

20. The semiconductor device of claim 1, wherein the contact shielding structure comprises a material and/or dopant concentration that is different from that of the drift region.

21. A semiconductor device, comprising:
a semiconductor layer structure comprising a drift region of a first conductivity type and a well region of a second conductivity type above the drift region;
a gate on the semiconductor layer structure adjacent the well region;
a support shielding structure of the second conductivity type that vertically extends from the well region into the drift region and is spaced apart from the gate; and
a bridge shielding structure of the second conductivity type that laterally extends from the support shielding structure towards the gate,
wherein at least one of the support shielding structure or the bridge shielding structure comprises a plurality of discrete segments.

22. The semiconductor device of claim 21, wherein the discrete segments longitudinally extend in one or more lateral directions, respectively.

23. The semiconductor device of claim 22, further comprising:
a bottom shielding structure of the second conductivity type in the drift region under the gate,
wherein the bridge shielding structure laterally extends from the support shielding structures to contact the bottom shielding structure.

24.-26. (canceled)

27. The semiconductor device of claim 22, wherein the support shielding structure comprises a material and/or dopant concentration that is different from that of the bridge shielding structure.

28. (canceled)

29. A semiconductor device, comprising:
a semiconductor layer structure comprising a drift region of a first conductivity type and a well region of a second conductivity type above the drift region;
a gate on the semiconductor layer structure adjacent the well region; and
a contact shielding structure of the second conductivity type that vertically extends from the well region into the drift region and comprises a plurality of segments with respective spacings therebetween,
wherein the respective spacings are smaller than respective widths of the segments.

30. The semiconductor device of claim 29, wherein the respective widths of the segments are about 0.1 microns to about 20 microns.

31. The semiconductor device of claim 29, wherein the semiconductor device has an avalanche capability that is increased by about 5% to about 30% and an on-resistance that is reduced by about 5% to about 30%, in comparison to a semiconductor device having a continuous shielding pattern.

32. The semiconductor device of claim 29, wherein the segments longitudinally extend in one or more lateral directions, respectively, with the respective spacings therebetween.

33.-38. (canceled)
